(19) United States
(12) Patent Application Publication
(10) Pub. No.: US 2025/0056974 A1
(43) Pub. Date: Feb. 13, 2025

(54) DISPLAY APPARATUS AND METHOD OF MANUFACTURING THE SAME

(71) Applicant: Samsung Display Co., Ltd., Yongin-si (KR)

(72) Inventors: Heewoon Im, Yongin-si (KR); Yoolguk Kim, Yongin-si (KR); Hyeonsik Kim, Yongin-si (KR); Jaehyun Park, Yongin-si (KR); Sangho Lee, Yongin-si (KR); Wonkyu Choe, Yongin-si (KR)

(21) Appl. No.: 18/796,593

(22) Filed: Aug. 7, 2024

(30) Foreign Application Priority Data
Aug. 11, 2023 (KR) 10-2023-0105633

(51) Int. Cl. H10K 59/122; H10K 59/12; H10K 102/00

(52) U.S. Cl. CPC H10K 59/122; H10K 59/1201; H10K 2102/351

(57) ABSTRACT

A display apparatus includes a substrate, a pixel electrode over the substrate, a bank layer defining an opening exposing a central portion of the pixel electrode, and having a lateral surface facing the opening, a portion of the lateral surface of the bank layer defining a trench dug in a direction away from the opening at a lower portion of the bank layer to expose an upper surface of the pixel electrode, an intermediate layer in the opening to correspond to the pixel electrode, and an opposite electrode covering the bank layer and the intermediate layer.

### CROSS-REFERENCE TO RELATED APPLICATION

The present application claims priority to, and the benefit of, Korean Patent Application No. 10-2023-0105633, filed on Aug. 11, 2023, in the Korean Intellectual Property Office, the entire disclosure of which is incorporated herein by reference.

### BACKGROUND

### 1. Field

One or more embodiments relate to a structure of a display apparatus and a method of manufacturing the same.

### 2. Description of the Related Art

Generally, a display apparatus includes light-emitting elements and thin-film transistors on a substrate and operates by having the light-emitting elements emit light. A light-emitting element is an element configured to convert electrical energy into light energy. Examples of a light-emitting element include an organic light-emitting element in which an emission material is an organic material, and a quantum-dot light-emitting element in which an emission material is a quantum dot.

For example, each pixel of a display apparatus includes a light-emitting element including an intermediate layer, wherein the intermediate layer includes an emission layer between a pixel electrode and an opposite electrode. A display apparatus is configured to control whether each pixel emits light, or the degree of light emission, through a thin-film transistor electrically connected to the pixel electrode. Some layers included in the intermediate layer of the light-emitting element are commonly provided over a plurality of light-emitting elements.

### SUMMARY

One or more embodiments include a display apparatus including a light-emitting element having a high emission efficiency and a long lifespan. However, such an aspect is just an example, and the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate, a pixel electrode over the substrate, a bank layer defining an opening exposing a central portion of the pixel electrode, and having a lateral surface facing the opening, a portion of the lateral surface of the bank layer defining a trench dug in a direction away from the opening at a lower portion of the bank layer to expose an upper surface of the pixel electrode, an intermediate layer in the opening to correspond to the pixel electrode, and an opposite electrode covering the bank layer and the intermediate layer.

The pixel electrode overlapping the trench and the opening may expose a greater area of the upper surface of the pixel electrode than overlapping only the opening.

The bank layer may cover an end of the pixel electrode.

The trench may be filled with the intermediate layer.

A width of the trench in a direction parallel to the substrate may be about ¼^{th} to about ⅓^{rd} of a width of a lower surface of the bank layer in a case where the trench is not formed.

A width of the trench in a direction parallel to the substrate may be about 200 Å to about 400 Å.

A thickness of the trench in a direction perpendicular to the substrate may be about 300 Å to about 1000 Å.

The trench may include a lower trench depressed in lateral surfaces of the bank layer, and an upper trench that is less deeply depressed than the lower trench.

A thickness of the trench in a direction perpendicular to the substrate may be about 600 Å to about 2000 Å.

A first pixel, a second pixel, and a third pixel respectively configured to emit light of different colors may be arranged above the substrate, wherein the pixel electrode includes a first pixel electrode corresponding to the first pixel, a second pixel electrode corresponding to the second pixel, and a third pixel electrode corresponding to the third pixel, wherein the bank layer defines a first opening exposing the first pixel electrode, a second opening exposing the second pixel electrode, and a third opening exposing the third pixel electrode, and wherein the intermediate layer includes a first intermediate layer in the first opening, a second intermediate layer in the second opening, and a third intermediate layer in the third opening.

The first pixel may be configured to emit light in a wavelength band of about 580 nm to about 780 nm, wherein the second pixel is configured to emit light in a wavelength band of about 495 nm to about 580 nm, and wherein the third pixel is configured to emit light in a wavelength band of about 380 nm to about 495 nm.

The first intermediate layer and the second intermediate layer may include an emission layer including quantum dots, wherein the third intermediate layer includes an emission layer including an organic material.

The trench may be in a lateral surface of the bank layer facing the first opening and in a lateral surface of the bank layer facing the second opening, and might not be in a lateral surface of the bank layer facing the third opening.

The trench may be in a lateral surface of the bank layer facing the third opening, might not be in a lateral surface of the bank layer facing the first opening, and might not be in a lateral surface of the bank layer facing the second opening.

The trench may be in only a lateral surface adjacent to the third opening among lateral surfaces of the bank layer facing the first opening, and may be in only a lateral surface adjacent to the third opening among lateral surfaces of the bank layer facing the second opening.

The trench may be in only a lateral surface away from the third opening among lateral surfaces of the bank layer facing the first opening, may be in only a lateral surface away from the third opening among lateral surfaces of the bank layer facing the second opening, and may be on a lateral surface of the bank layer facing the third opening.

According to one or more embodiments, a method of manufacturing a display apparatus includes forming a pixel electrode over a substrate, forming a sacrificial layer on an upper surface of the pixel electrode, forming a bank layer on the pixel electrode, forming an opening in the bank layer corresponding to the pixel electrode, forming a trench in a portion of a lateral surface of the bank layer facing the opening by removing the sacrificial layer, forming an intermediate layer in the opening to correspond to the pixel electrode, and forming an opposite electrode covering the bank layer and the intermediate layer.

The trench may be in a lower portion of the bank layer, and may expose the upper surface of the pixel electrode.

The sacrificial layer may have a smaller area than the pixel electrode.

The bank layer may cover an end of the pixel electrode.

The sacrificial layer may include at least one of tungsten oxide (WOₓ) or molybdenum oxide (MoOₓ).

The sacrificial layer may be removed by washing with deionized (DI) water.

The forming of the sacrificial layer may include forming a lower sacrificial layer on the pixel electrode having an area that is less than the pixel electrode in a plan view, and forming an upper sacrificial layer on the lower sacrificial layer having an area that less than the lower sacrificial layer in a plan view.

The trench may include a lower trench depressed in part of lateral surfaces of the bank layer, and an upper trench that is less deeply depressed than the lower trench.

A first pixel, a second pixel, and a third pixel may be respectively configured to emit light of different colors are arranged above the substrate, wherein the forming of the pixel electrode includes forming a first pixel electrode corresponding to the first pixel, a second pixel electrode corresponding to the second pixel, and a third pixel electrode corresponding to the third pixel, wherein the forming of the bank layer includes forming a first opening exposing the first pixel electrode, a second opening exposing the second pixel electrode, and a third opening exposing the third pixel electrode, and wherein the forming of the intermediate layer includes forming a first intermediate layer in the first opening, a second intermediate layer in the second opening, and a third intermediate layer in the third opening.

The forming of the intermediate layer may include discharging a material for forming an emission layer into the opening through an inkjet process, and drying the material for forming the emission layer.

Each of the forming of the first intermediate layer and the forming of the second intermediate layer may include forming an emission layer including quantum dots, wherein the forming of the third intermediate layer includes forming an emission layer including an organic material.

The trench may be in only a lateral surface of the bank layer facing the first opening and a lateral surface of the bank layer facing the second opening.

The drying may be adjusted to a drying condition of the third intermediate layer.

The trench may be in only a lateral surface of the bank layer facing the third opening.

The drying may be adjusted to drying conditions of the first intermediate layer and the second intermediate layer.

The trench may be in only a lateral surface adjacent to the third opening among lateral surfaces of the bank layer facing the first opening, and may be in only a lateral surface adjacent to the third opening among lateral surfaces of the bank layer facing the second opening.

The trench may be in only a lateral surface away from the third opening among lateral surfaces of the bank layer facing the first opening, may be in only a lateral surface away from the third opening among lateral surfaces of the bank layer facing the second opening, and may be in a lateral surface of the bank layer facing the third opening.

### BRIEF DESCRIPTION OF DRAWINGS

The above and other aspects of embodiments of the disclosure will be more apparent from the following description taken in conjunction with the accompanying drawings, in which:

FIG. 1 is a schematic perspective view of a display apparatus according to one or more embodiments;

FIG. 2 is an equivalent circuit diagram of a pixel circuit electrically connected to a light-emitting element included in a pixel of the display apparatus of FIG. 1;

FIGS. 3A and 3B are schematic cross-sectional views of a display apparatus according to embodiments;

FIG. 4 is a schematic plan view of a display apparatus according to one or more embodiments;

FIG. 5 is a schematic cross-sectional view of the display apparatus of FIG. 4, taken along the line I-I′ of FIG. 4;

FIGS. 6A to 6G are schematic cross-sectional views showing a process of manufacturing a display apparatus according to one or more embodiments;

FIG. 7 is a schematic cross-sectional view of a display apparatus according to one or more other embodiments;

FIG. 8 is a schematic cross-sectional view of a display apparatus according to one or more other embodiments;

FIG. 9 is a schematic cross-sectional view of a display apparatus according to one or more other embodiments; and

FIG. 10 is a schematic cross-sectional view of a display apparatus according to one or more other embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions such as “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

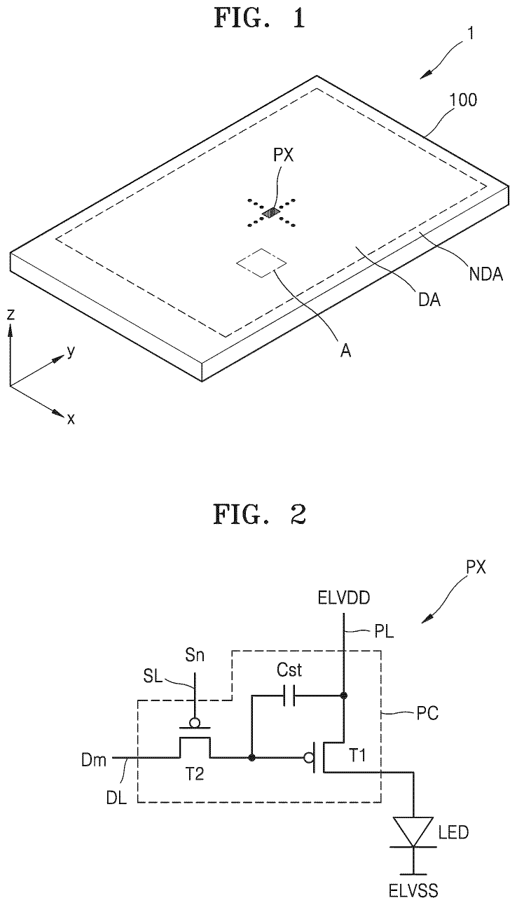

FIG. 1 is a schematic perspective view of a display apparatus 1 according to one or more embodiments.

Referring to FIG. 1, the display apparatus 1 may include a display area DA and a non-display area NDA on a substrate 100.

The display area DA may be configured to display images. A plurality of pixels PX two-dimensionally arranged in a plan view may be arranged in the display area DA. In the present specification, each pixel PX denotes a sub-pixel configured to emit light of a different color. Each pixel PX may be, for example, one of a red sub-pixel, a green sub-pixel, and a blue sub-pixel. The display apparatus 1 may be configured to display images by using light emitted from the plurality of pixels PX.

The non-display area NDA is a region configured not to display images, and the pixels PX are not arranged in the non-display area NDA. The non-display area NDA may surround the display area DA entirely. A driver or a voltage line configured to provide electrical signals or power to the pixels PX, may be arranged in the non-display area NDA. In one or more embodiments, a pad portion may be arranged in the non-display area NDA, wherein the pad portion is a region to which electronic elements or a printed circuit board may be electrically connected.

The display area DA may have a polygonal shape. As an example, as shown in FIG. 1, the display area DA may have a rectangular shape in which a horizontal length thereof is greater than a vertical length thereof. Alternately, the display area DA may have a square shape. Alternatively, the display area DA may have various shapes, such as an elliptical shape or a circular shape.

FIG. 2 is an equivalent circuit diagram of a pixel circuit electrically connected to a light-emitting element included in a pixel of the display apparatus of FIG. 1.

Referring to FIG. 2, the pixel PX may include a pixel circuit PC and a display element, for example, a light-emitting diode LED connected to the pixel circuit PC. The pixel circuit PC may include a first thin-film transistor T1, a second thin-film transistor T2, and a storage capacitor Cst. Each pixel PX may be configured to emit, for example, red, green, or blue light, or emit red, green, blue, or white light by using the light-emitting diode LED.

The second thin-film transistor T2 is a switching thin-film transistor, may be connected to a scan line SL and a data line DL, and may be configured to transfer a data voltage or a data signal Dm to the first thin-film transistor T1 according to a switching voltage or a switching signal Sn, the data voltage being input from the data line DL, and the switching voltage being input from the scan line SL. The storage capacitor Cst may be connected to the second thin-film transistor T2 and a driving voltage line PL, and may be configured to store a voltage corresponding to a difference between a voltage transferred from the second thin-film transistor T2 and a first power voltage ELVDD supplied to the driving voltage line PL.

The first thin-film transistor T1 is a driving thin-film transistor, may be connected to the driving voltage line PL and the storage capacitor Cst, and may be configured to control a driving current according to the voltage stored in the storage capacitor Cst, the driving current flowing from the driving voltage line PL to the light-emitting diode LED. The light-emitting diode LED may be configured to emit light having a preset brightness corresponding to the driving current. An opposite electrode (e.g., a cathode) of the light-emitting diode LED may receive a second power voltage ELVSS.

Although it is shown in FIG. 2 that the pixel circuit PC includes two thin-film transistors and one storage capacitor, the number of thin-film transistors and the number of storage capacitors may be variously changed depending on the design of the pixel circuit PC.

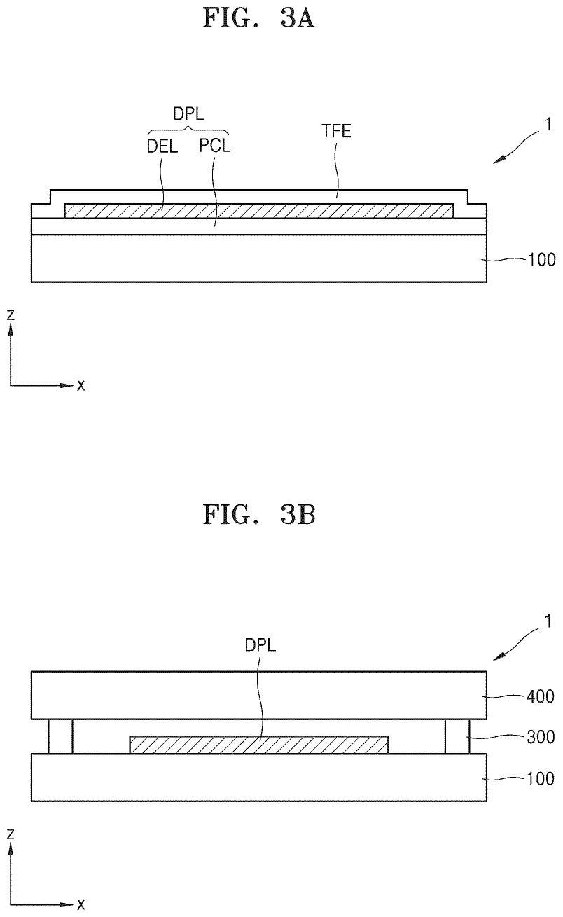

FIG. 3A is a schematic cross-sectional view of the display apparatus according to one or more embodiments, and FIG. 3B is a schematic cross-sectional view of a display apparatus according to one or more other embodiments.

Referring to FIG. 3A, a display layer DPL and a thin-film encapsulation layer TFE may be provided on the substrate 100 of the display apparatus 1. The display layer DPL may include a pixel circuit layer PCL and a display element layer DEL, wherein the pixel circuit layer PCL includes the pixel circuit and insulating layers, and the display element layer DEL is located on the pixel circuit layer PCL and includes a plurality of display elements.

The substrate 100 may include glass, metal, or polymer resin. The polymer resin may include, for example, polyethersulphone, polyacrylate, polyetherimide, polyethylene naphthalate, polyethylene terephthalate, polyphenylene sulfide, polyarylate, polyimide, polycarbonate, cellulose acetate propionate, or a mixture thereof. The substrate 100 may have a multi-layered structure including two layers each including the polymer resin, and a barrier layer including an inorganic material (such as silicon oxide (SiOₓ), silicon nitride (SiNₓ), and silicon oxynitride (SiON)) therebetween. However, various modifications may be made.

The display element layer DEL may include display elements, for example, an organic light-emitting element, a quantum-dot light-emitting element, and the like. The pixel circuit layer PCL may include the pixel circuit connected to the light-emitting element and the insulating layer. As an example, the pixel circuit layer PCL may include a plurality of transistors, a plurality of storage capacitors, and the insulating layers therebetween.

The display elements may be covered by an encapsulation member, such as the thin-film encapsulation layer TFE. The thin-film encapsulation layer TFE may include at least one inorganic encapsulation layer and at least one organic encapsulation layer, each covering the display element layer DEL. The inorganic encapsulation layer may include an inorganic insulating material, such as aluminum oxide (Al₂O₃), titanium oxide (TiO₂), tantalum oxide (Ta₂O₅), hafnium oxide (HfO₂) zinc oxide (ZnOₓ), silicon oxide (SiO₂), silicon nitride (SiNₓ), or silicon oxynitride (SiON). The organic encapsulation layer may include a polymer-based material. The polymer-based material may include an acryl-based resin, an epoxy-based resin, polyimide, and polyethylene. In one or more embodiments, the organic encapsulation layer may include acrylate.

Referring to FIG. 3B, the display layer DPL and an encapsulation substrate 400 may be provided on the substrate 100 of the display apparatus 1. A sealant (e.g., sealing member) 300 may be located between the substrate 100 and the encapsulation substrate 400. The encapsulation substrate 400 may be a transparent member. The substrate 100 and the encapsulation substrate 400 may be coupled to each other by the sealant 300, and a structure in which an inner space between the substrate 100 and the encapsulation substrate 400 is sealed may be provided. In this case, moisture absorbents or fillers may be located in the inner space. In one or more other embodiments, the sealant 300 may include a material cured by a laser beam. As an example, the sealant 300 may include frit. For example, the sealant 300 may include an organic sealant, such as a urethane-based resin, an epoxy-based resin, an acrylic resin, or an inorganic sealant, such as silicon. As a urethane-based resin, for example, urethane acrylate or the like may be used. As acrylic resin, for example, butyl acrylate, ethylhexyl acrylate, or the like may be used. The sealant 300 may include a material cured by heat.

In one or more embodiments, the display element layer DEL and the thin-film encapsulation layer TFE of FIG. 3A may be covered by the encapsulation substrate 400 and the sealant 300 of FIG. 3B.

A touch electrode layer may be located on the thin-film encapsulation layer TFE and/or the encapsulation substrate 400, and an optical functional layer may be located on the touch electrode layer, in one or more embodiments. The touch electrode layer may obtain coordinate information corresponding to an external input, for example, a touch event. The optical functional layer may reduce reflectivity of light (external light) incident toward the display apparatus 1 from the outside. Alternatively, the optical functional layer may increase color purity of light emitted from the display apparatus 1. In one or more embodiments, the optical functional layer may include a phase retarder and/or a polarizer. The phase retarder may include a film-type retarder or a liquid crystal-type retarder. The phase retarder may include a λ/2 phase retarder and/or a λ/4 phase retarder. The polarizer may include a film-type polarizer or a liquid crystal-type polarizer. The film-type polarizer may include a stretchable synthetic resin film, and the liquid crystal-type polarizer may include liquid crystals arranged in an arrangement (e.g., a predetermined arrangement). Each of the phase retarder and the polarizer may further include a protective film.

In one or more other embodiments, the optical functional layer may include a black matrix and color filters. The color filters may be arranged by accounting for colors of light emitted respectively from the pixels of the display apparatus 1. The color filters may each include red, green, or blue pigment or dye. Alternatively, the color filters may each further include quantum dots in addition to the pigment or dye. Alternatively, some of the color filters may not include pigment or dye, and may include scattering particles, such as titanium oxide.

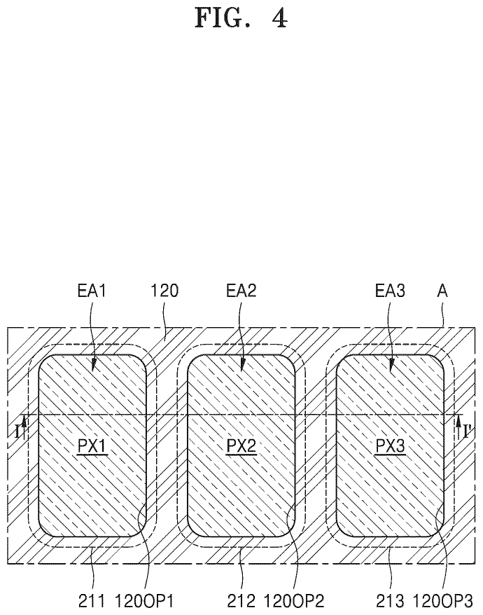

FIG. 4 is a schematic plan view of a display apparatus according to one or more embodiments.

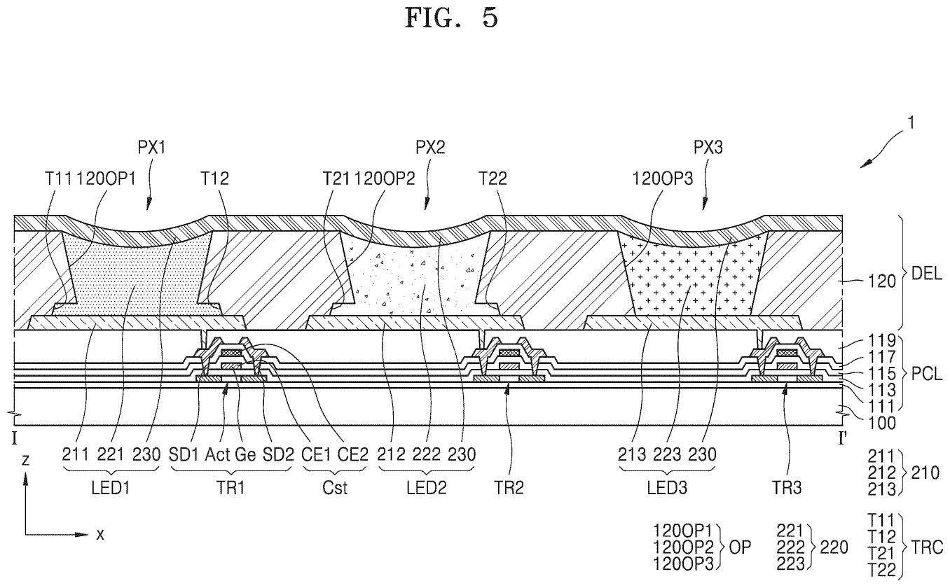

Referring to FIG. 4, the display apparatus 1 may include the plurality of pixels PX (see FIG. 1). The plurality of pixels PX (see FIG. 1) may include a first pixel PX1, a second pixel PX2, and a third pixel PX3. The first pixel PX1 may include a first light-emitting diode LED1 (see FIG. 5), the second pixel PX2 may include a second light-emitting diode LED2 (see FIG. 5), and the third pixel PX3 may include a third light-emitting diode LED3. The first pixel PX1, the second pixel PX2, and the third pixel PX3 may be respectively configured to emit light of different colors. As an example, the first pixel PX1 may be configured to emit red light, the second pixel PX2 may be configured to emit green light, and the third pixel PX3 may be configured to emit blue light. Red light may be light in a wavelength band of about 580 nm to about 780 nm, blue light may be light in a wavelength band of about 380 nm to about 495 nm, and green light may be light in a wavelength band of about 495 nm to about 580 nm.

Each light-emitting diode may include a pixel electrode, an opposite electrode, and an intermediate layer therebetween. Accordingly, the first pixel PX1 may include a first pixel electrode 211 of the first light-emitting diode LED1 (see FIG. 5), the second pixel PX2 may include a second pixel electrode 212 of the second light-emitting diode LED2 (see FIG. 5), and the third pixel PX3 may include a third pixel electrode 213 of the third light-emitting diode LED3 (see FIG. 5). The first pixel electrode 211, the second pixel electrode 212, and the third pixel electrode 213 may be apart from each other over the substrate 100 (see FIG. 5). In the present specification, “in a plan view” means a plane when viewed in a direction perpendicular to the substrate 100. That is, “A and B apart from each other in a plan view” means “A and B apart from each other when viewed in a direction perpendicular to the substrate 100.”

A bank layer 120 may be located on the first pixel electrode 211, the second pixel electrode 212, and the third pixel electrode 213, and may cover the edges of each of the first pixel electrode 211, the second pixel electrode 212, and the third pixel electrode 213. That is, the bank layer 120 may include a first opening 120OP1 exposing the central portion of the first pixel electrode 211, a second opening 120OP2 exposing the central portion of the second pixel electrode 212, and a third opening 120OP3 exposing the central portion of the third pixel electrode 213.

In one or more embodiments, emission layers configured to emit light may be respectively located in the first opening 120OP1, the second opening 120OP2, the third opening 120OP3 of the bank layer 120. The opposite electrode may be located on the emission layers. As described above, a stack structure of the pixel electrode, the emission layer, and the opposite electrode may form one light-emitting diode. One opening of the bank layer 120 may correspond to one light-emitting diode and define an emission area.

As an example, an emission layer configured to emit red light may be located in the first opening 120OP1, which may define a first emission area EA1. Similarly, an emission layer configured to emit green light may be located in the second opening 120OP2, which may define a second emission area EA2. An emission layer configured to emit blue light may be located in the third opening 120OP3, which may define a third emission area EA3. Accordingly, the size of the area of the first opening 120OP1 is the same as the size of the area of the first emission area EA1, the size of the area of the second opening 120OP2 is the same as the size of the area of the second emission area EA2, and the size of the area of the third opening 120OP3 is the same as the size of the area of the third emission area EA3.

Each of the first opening 120OP1, the second opening 120OP2, and the third opening 120OP3 may have a polygonal shape when viewed in a direction (a z-axis direction) perpendicular to the substrate 100 (see FIG. 5). In other words, each of the first emission area EA1, the second emission area EA2, and the third emission area EA3 may have a polygonal shape when viewed in a direction perpendicular to the substrate 100. It is shown in FIG. 4 that each of the first emission area EA1, the second emission area EA2, and the third emission area EA3 has a quadrangular shape, for example, a quadrangular shape having round edges when viewed in the direction perpendicular to the substrate 100. However, the present disclosure is not limited thereto. As an example, each of the first emission area EA1, the second emission area EA2, and the third emission area EA3 may have a circular shape or an elliptical shape when viewed in a direction (the z-axis direction) perpendicular to the substrate 100.

FIG. 5 is a schematic cross-sectional view of the display apparatus of FIG. 4, taken along the line I-I′ of FIG. 4.

Referring to FIG. 5, the pixel circuit layer PCL may be located on the substrate 100. The pixel circuit layer PCL may include first to third transistors TR1, TR2, and TR3, a buffer layer 111, a first gate insulating layer 113, a second gate insulating layer 115, an interlayer insulating layer 117, and a planarization layer 119 under and/or above elements of the transistors. Here, each of the first to third transistors TR1, TR2, and TR3 may correspond to the first thin-film transistor T1 shown in FIG. 2. Because the structure of the second transistor TR2 and the third transistor TR3 is similar to the structure of the first transistor TR1, repeated description thereof is omitted.

The buffer layer 111 may include an inorganic insulating material, such as silicon nitride (SiNₓ), silicon oxynitride (SiON), or silicon oxide (SiOₓ), and may include a single-layered structure or a multi-layered structure including the inorganic insulating materials. The buffer layer 111 may increase the flatness of the upper surface of the substrate 100 and prevent or reduce the penetration of impurities from the substrate 100 and the like into a semiconductor layer Act.

The first transistor TR1 may include the semiconductor layer Act, and the semiconductor layer Act may include polycrystalline silicon. Alternatively, the semiconductor layer Act may include amorphous silicon, an oxide semiconductor material, or an organic semiconductor material.

A gate electrode Ge may overlap a portion of the semiconductor layer Act. The gate electrode Ge may include a conductive material. As an example, the gate electrode Ge may include a conductive material including molybdenum (Mo), aluminum (Al), copper (Cu), or titanium (Ti) and have a single-layered structure or a multi-layered structure including the above materials.

The first gate insulating layer 113 between the semiconductor layer Act and the gate electrode Ge may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

The second gate insulating layer 115 may cover the gate electrode Ge. Similar to the first gate insulating layer 113, the second gate insulating layer 115 may include an inorganic insulating material including silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

An upper electrode CE2 of the storage capacitor Cst may be arranged on the second gate insulating layer 115. The upper gate electrode CE2 may overlap the gate electrode Ge therebelow. In this case, the gate electrode Ge and the upper electrode CE2 overlapping each other with the second gate insulating layer 115 therebetween may constitute the storage capacitor Cst. That is, the gate electrode Ge may serve as a lower electrode CE1 of the storage capacitor Cst.

As described above, the storage capacitor Cst may overlap the first transistor TR1. In one or more embodiments, the storage capacitor Cst may be formed not to overlap the first transistor TR1.

The upper electrode CE2 may include a conductive material, such as aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), or copper (Cu), and may include a single-layered structure or a multi-layered structure including the above materials.

The interlayer insulating layer 117 may cover the upper electrode CE2. The interlayer insulating layer 117 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The interlayer insulating layer 117 may include a single-layered structure or a multi-layered structure including the inorganic insulating material.

A drain electrode SD1 and a source electrode SD2 may each be located on the interlayer insulating layer 117. The drain electrode SD1 and the source electrode SD2 may each be electrically connected to the semiconductor layer Act through a contact hole formed in the first gate insulating layer 113, the second gate insulating layer 115, and the interlayer insulating layer 117. The drain electrode SD1 and the source electrode SD2 may each include a material having high conductivity. The drain electrode SD1 and the source electrode SD2 may each include a conductive material including molybdenum (Mo), aluminum (AI), copper (Cu), or titanium (Ti), and may include a single-layered structure or a multi-layered structure including the above materials. In one or more embodiments, the drain electrode SD1 and the source electrode SD2 may each have a multi-layered structure of Ti/Al/Ti. In one or more embodiments, one of the drain electrode SD1 and the source electrode SD2 may be omitted, a portion of the semiconductor layer Act may replace this.

The planarization layer 119 may cover the first transistor TR1, and may include/define a contact hole exposing a portion of the first transistor TR1. The planarization layer 119 may include an organic insulating layer. The planarization layer 119 may include an organic insulating material including a general-purpose polymer, such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The display element layer DEL may be located on the pixel circuit layer PCL. The display element layer DEL may include the first to third light-emitting diodes LED1, LED2, and LED3 and the bank layer 120 under and/or above elements of the light-emitting diode. In one or more embodiments, the first and second light-emitting diodes LED1 and LED2 may be quantum-dot light-emitting elements, and the third light-emitting diode LED3 may be an organic light-emitting element. As an example, the first light-emitting diode LED1 configured to emit red light and the second light-emitting diode LED2 configured to emit green light may include an emission layer including quantum dots, and the third light-emitting diode LED3 configured to emit blue light may include an emission layer not including quantum dots and including only an organic material.

Each of the first to third light-emitting diodes LED1, LED2, and LED3 may include a pixel electrode 210. The pixel electrode 210 may include a first pixel electrode 211 forming the first light-emitting diode LED1, a second pixel electrode 212 forming the second light-emitting diode LED2, and a third pixel electrode 213 forming the third light-emitting diode LED3. The first to third pixel electrodes 211, 212, and 213 may be located on the pixel circuit layer PCL. The first pixel electrode 211 may be electrically connected to the drain electrode SD1 or the source electrode SD2 of the first transistor TR1 through a contact hole passing through the planarization layer 119. As shown in FIG. 5, the first pixel electrode 211, the second pixel electrode 212, and the third pixel electrode 213 may be apart from each other by a preset distance in a second direction (e.g., an x-axis direction).

The pixel electrode 210 may be a reflective electrode, a semi-transmissive electrode, or a transmissive electrode. To form the pixel electrode, which is a transmissive electrode, indium tin oxide (ITO), indium zinc oxide (IZO), tin oxide (SnO₂), zinc oxide (ZnO), or any combination thereof can be used as a material for the pixel electrode. To form the pixel electrode 210, which is a semi-transmissive electrode or a reflective electrode, magnesium (Mg), silver (Ag), aluminum (AI), aluminum-lithium (Al—Li), calcium (Ca), magnesium-indium (Mg—In), magnesium-silver (Mg—Ag), or any combination thereof may be used as a material for the pixel electrode. The pixel electrode 210 may have a single-layered structure having a single layer or a multi-layered structure including a plurality of layers. As an example, the pixel electrode 210 may have a three-layered structure of ITO/Ag/ITO.

The bank layer 120 may be located on the pixel circuit layer PCL. The bank layer 120 may cover the edges of the first to third pixel electrodes 211, 212, and 213. For example, the bank layer 120 may be in direct contact with the upper surface and the lateral surfaces of the end of the pixel electrode 210.

The bank layer 120 may include various materials. In one or more embodiments, the bank layer 120 may include an organic material, such as acrylic, BCB (benzocyclobutene), or HMDSO (hexamethyldisiloxane). In one or more other embodiments, the bank layer 120 may include a photoresist, that is, photosensitive resin. For example, the bank layer 120 may include a negative type photoresist that undergoes a reaction, such as crosslinking upon light exposure.

The bank layer 120 may include the first opening 120OP1 exposing the central portion of the first pixel electrode 211, the second opening 120OP2 exposing the central portion of the second pixel electrode 212, and the third opening 120OP3 exposing the central portion of the third pixel electrode 213. As an example, the bank layer 120 may define the first emission area EA1 of the first light-emitting diode LED1, the second emission area EA2 of the second light-emitting diode LED2, and the third emission area EA3 of the third light-emitting diode LED3. The bank layer 120 may prevent or reduce the likelihood of arcs and the like occurring at the edges of the pixel electrodes 210 by increasing a distance between the edges of the pixel electrodes 210 and an opposite electrode 230.

An emission layer 220 may be located in the opening of the bank layer 120. The emission layer 220 may include a first emission layer 221 forming the first light-emitting diode LED1, a second emission layer 222 forming the second light-emitting diode LED2, and a third emission layer 223 forming the third light-emitting diode LED3. As an example, the first emission layer 221 may be located on the first pixel electrode 211 and may be located in the first opening 120OP1. Likewise, the second emission layer 222 may be located on the second pixel electrode 212 and may be located in the second opening 120OP2. The third emission layer 223 may be located on the third pixel electrode 213 and may be located in the third opening 120OP3.

In one or more embodiments, the first emission layer 221 and the second emission layer 222 may include quantum dots. For example, the quantum dots included in the first emission layer 221 and the second emission layer 222 may serve as dopants, and the emission layer may further include a host and/or delayed fluorescent material. The quantum dots denote crystals of a semiconductor compound. The quantum dots may be configured to emit light in various emission wavelengths depending on the size of the crystal. The quantum dots may be configured to emit light in various emission wavelengths by adjusting the ratio of elements constituting the quantum dots. As an example, a diameter of the quantum dots may be about 1 nm to about 10 nm.

Quantum dots may be synthesized by a wet chemical process, a metal organic chemical vapor deposition process, a molecular beam epitaxy process, or a similar process. The wet chemical process is a method of mixing an organic solvent with a precursor material and then growing quantum dot crystals. When the crystal grows, the organic solvent naturally acts as a dispersant coordinated on the surface of the quantum dot crystal and controls the growth of the crystal. Accordingly, the wet chemical process may be more suitable than vapor deposition, such as metal organic chemical vapor deposition (MOCVD) or molecular beam epitaxy (MBE), and may be configured to control the growth of quantum dot particles through a process at low costs.

The quantum dot may include one of a Group II-VI semiconductor compound, a Group III-V semiconductor compound, a Group I-III-VI semiconductor compound, a Group IV-VI semiconductor compound, a Group IV element or compound, and an arbitrary combination thereof.

Examples of a Group II-VI semiconductor compound may include one of a two-element compound including CdS, CdSe, CdTe, ZnS, ZnSe, ZnTe, ZnO, HgS, HgSe, HgTe, MgSe, or MgS, a three-element compound including CdSeS, CdSeTe, CdSTe, ZnSeS, ZnSeTe, ZnSTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS, a four-element compound including HgZnSTe, CdZnSeS, CdZnSe, CdZnSeS, or CdSeTeSe, or the like, and an arbitrary combination thereof.

Examples of a Group III-V semiconductor compound may include one of a two-element compound including GaN, GaP, GaAs, GaSb, AlN, AlP, AlAs, AlSb, InN, InP, InAs, or InSb, a three-element compound including GaNP, GaNAs, GaNSb, GaPAs, GaPSb, AlNP, AlNAs, AlNSb, AlPAs, AlPSb, InGaP, InNP, InAlP, InNAs, InNSb, InPAs, or InPSb, or a four-element compound including GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb, or an arbitrary combination thereof. A Group III-V semiconductor compound may further include a Group II element. Examples of a Group III-V semiconductor compound further including a Group II element may include InZnP, InGaZnP, or InAlZnP.

Examples of a Group III-VI semiconductor compound may include one of a two-element compound including GaS, Ga₂S₃, GaSe, Ga₂Se₃, GaTe, InS, InSe, In₂S₃, In₂Se₃, or InTe, a three-element compound including InGaS₃ or InGaSe₃, and an arbitrary combination thereof.

Examples of a Group I-III-VI semiconductor compound may include one of a three-element compound including AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, or AgAlO₂, a four-element compound including AgInGaS₂, AgInGaSe₂, or CuInGaS, or an arbitrary combination thereof.

Examples of a Group IV-VI semiconductor compound may include one of a two-element compound including SnS, SnSe, SnTe, PbS, PbSe, or PbTe, a three-element compound including SnSeS, SnSeTe, SnSTe, PbSeS, PbSeTe, PbSTe, SnPbS, and SnPbSe, or SnPbTe, a four-element compound including SnPbSSe, SnPbSeTe, or SnPbSTe, or an arbitrary combination thereof.

Examples of a Group IV element or compound may include one of a single element including Si or Ge, a two-element compound including SiC or SiGe, or an arbitrary combination thereof.

Each element included in a multi-element compound, such as a two-element compound, a three-element compound, and a four-element compound may be present in a particle in a substantially uniform concentration or a non-uniform concentration. That is, the chemical formula refers to the type of elements included in the compound, and the element ratio within the compound may be different. For example, AgInGaS₂ may mean AgInₓGa₁₋ₓS₂, x being a real number between 0 and 1.

A quantum dot may have a single structure in which the concentration of each element included in the relevant quantum dot is substantially uniform, or a double structure of a core-shell. As an example, a material of the core may be different from a material of the shell. The shell may cover at least a portion of the core.

The core may include Cd, Zn, Hg, Mg, Ga, Al, In, Sn, Pb, Se, Te, P, or Sb.

The shell of a quantum dot may serve as a protective layer that prevents or reduces a chemical change of the core to maintain a semiconductor characteristic and/or may serve as a charging layer for giving an electrophoretic characteristic to the quantum dot. The shell may include a single layer or a multi-layer. An interface between the core and the shell may have a concentration gradient in which the concentration of an element existing in the shell reduces toward the center.

Examples of the shell of the quantum dot include oxide of metal or non-metal, a semiconductor compound, or a combination thereof. Examples of oxides of metals or non-metals may include one of a two-element compound including SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or a three-element compound including MgAl₂O₄, CoFe₂O₄, NiFe₂O₄, CoMn₂O₄, or an arbitrary combination thereof. Examples of the semiconductor compound may include one of a Group III-VI semiconductor compound, a Group II-VI semiconductor compound, a Group III-V semiconductor compound, a Group I-III-VI semiconductor compound, a Group IV-VI semiconductor compound, or an arbitrary combination thereof as described in the present specification. As an example, the semiconductor compound may include one of CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AIP, AlSb, or an arbitrary combination thereof.

Each element included in a multi-element compound, such as a two-element compound or a three-element compound, may be present in a particle in a substantially uniform concentration or a non-uniform concentration. That is, the chemical formula refers to the type of elements included in the compound, and the element ratio within the compound may be different.

A quantum dot may have a full width of half maximum (FWHM) of a light emission wavelength spectrum of about 45 nm or less, for example about 40 nm or less, and more for example about 30 nm or less. Within this range, color purity or color reproduction may be improved. In addition, because light emitted from the quantum dot is emitted in all directions, a viewing angle of light may be improved.

In addition, the shape of the quantum dot may be a spherical shape, a pyramid shape, a multi-arm shape, a cubic shape, a nanoparticle, a nanotube, a nanowire, a nanofiber, a nano plate particle, or the like.

Because an energy band gap may be adjusted by adjusting the size of the quantum dot or the element ratio in the quantum dot compound, light in various wavelengths may be obtained from the quantum dot emission layer. Accordingly, the light-emitting element configured to emit light having various wavelengths may be implemented by using the quantum dots (using quantum dots of different sizes or using different element ratios in the quantum dot compound). For example, the size of the quantum dot or the element ratio in the quantum dot compound may be adjusted such that red, green, and/or blue light is emitted. In addition, the quantum dots may be configured such that light in various colors is combined to emit white light.

The third emission layer 223 may be an emission layer not including quantum dots and including only an organic material. For example, the third emission layer 223 may include an organic material including a fluorescent or phosphorous material emitting red, green, blue, or white light. The third emission layer 223 may be an organic emission layer including a low-molecular weight organic material or a polymer organic material. As an example, the third emission layer 223 is an organic emission layer and may include copper phthalocyanine, tris-8-hydroxyquinoline aluminum, poly-phenylenevinylene-based material, or polyfluorene-based material.

In addition, in one or more embodiments, the intermediate layer may further include a common layer located between the pixel electrode 210 and the emission layer 220, and/or between the emission layer 220 and the opposite electrode 230. Hereinafter, a common layer located between the pixel electrode 210 and the emission layer 220 is referred to as a first common layer, and a common layer located between the emission layer 220 and the opposite electrode 230 is referred to as a second common layer. The first common layer and the second common layer may each include an organic material.

The first common layer is a hole transport region, and may include a hole injection layer, a hole transport layer, an emission auxiliary layer, an electron-blocking layer, or an arbitrary combination thereof. As an example, the first common layer may have a multi-layered structure of a hole injection layer/hole transport layer, a hole injection layer/hole transport layer/emission auxiliary layer, a hole injection layer/emission auxiliary layer, a hole transport layer/emission auxiliary layer, or a hole injection layer, which are sequentially stacked from the pixel electrode 210.

The second common layer is an electron transport region, and may include a buffer layer, a hole-blocking layer, an electron control layer, an electron transport layer, an electron injection layer, or an arbitrary combination thereof. As an example, the electron transport region may have a structure of an electron transport layer/electron injection layer, a hole-blocking layer/electron transport layer/electron injection layer, an electron control layer/electron transport layer/electron injection layer, or a buffer layer/electron transport layer/electron injection layer, which are sequentially stacked from the emission layer 220.

The opposite electrode 230 may cover the emission layer 220 and the bank layer 120. As an example, the opposite electrode 230 may be integrally provided to cover the entire surface of the substrate 100 to cover the first emission layer 221, the second emission layer 222, and the third emission layer 223. A metal, alloy, electrically conductive compound, or an arbitrary combination thereof having a low work function may be used as a material for the opposite electrode 230. The opposite electrode 230 may include lithium (Li), silver (Ag), magnesium (Mg), aluminum (AI), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The opposite electrode 230 may be a transmissive electrode, a semi-transmissive electrode, or a reflective electrode. The opposite electrode 230 may have a single-layered structure, which is a single layer, or a multi-layered structure having a plurality of layers.

That is, the display apparatus 1 may have a structure including both a quantum-dot light-emitting element and an organic light-emitting element. The quantum-dot light-emitting element has relatively low manufacturing costs and suitable color coordinates. However, in the case of the light-emitting element configured to emit blue light, the organic light-emitting element may have a longer life than the quantum-dot light-emitting element. In the display apparatus according to one or more embodiments, because the first light-emitting diode LED1 and the second light-emitting diode LED2 employ the quantum-dot light-emitting elements, and the third light-emitting diode LED3 employs the organic light-emitting element, color purity and color reproduction may be improved, and thus, the display apparatus may not only have suitable emission characteristics, but also may implement a long lifespan. However, the present disclosure is not limited to the structure in which the first light-emitting diode LED1 and the second light-emitting diode LED2 employ the quantum-dot light-emitting elements, and the third light-emitting diode LED3 employs the organic light-emitting element. The first light-emitting diode LED1 or the second light-emitting diode LED2 may employ the organic light-emitting element, and the third light-emitting diode LED3 may employ the quantum-dot light-emitting element.

Because the display apparatus 1 includes both the quantum-dot light-emitting element and the organic light-emitting element, drying deviations may occur during a drying process of the emission layer 220. For example, a material for forming the emission layer is discharged to the opening of the bank layer 120 through an inkjet process, and then the emission layer may be formed by drying the material for forming the emission layer through the drying process. Because the first emission layer 221 and the second emission layer 222 may include the quantum dots, while the third emission layer 223 may include only the organic material, the material of the first emission layer 221 and the second emission layer 222 may be different from the material of the third emission layer 223, and thus, conditions required during the drying process may be different from each other.

Convective flow and Marangoni flow may occur in the material for forming the emission layer due to differences in evaporation rate and/or surface tension during the drying process. Generally, because liquid is dried from the edge, the liquid inside the material for forming the emission layer flows to the edge due to convection. In other words, because the liquid tends to maintain its spherical shape due to surface tension, when the edge portion of the liquid evaporates first, the liquid inside flows to the edge and moves to maintain its original shape as much as possible. Accordingly, solutes that move from the inside of the material for forming the emission layer accumulate at the edges, and as the liquid continues to evaporate, solutes may continue to accumulate. As described above, a phenomenon in which the solute is pushed out by the solvent due to a difference in evaporation rate and piles up in a ring shape from the outside may be referred to as a coffee-ring effect. Due to this coffee-ring effect, when the drying conditions are not optimal for the material for forming the emission layer, the accumulation of the material on the outer portion may become severe, and the thickness uniformity of the emission layer 220 may decrease. For example, the thickness uniformity of the emission layer 220 affects the emission efficiency and lifespan efficiency of the light-emitting element. When drying conditions are not optimized, the thickness non-uniformity may become severe due to the coffee-ring effect, thereby lowering the efficiency of the light-emitting element.

As shown in FIG. 5, in the display apparatus 1 in which the quantum-dot light-emitting element and the organic light-emitting element are arranged together, drying conditions of the drying process required for each emission layer 220 may be different. Because the material of the emission layer including the quantum dots and the material the emission layer including only the organic material are different from each other, the drying conditions required for respective materials are different. When the drying process is performed with the drying condition improved or optimized for one side, the thickness uniformity on the other side may be lowered due to the coffee-ring effect. As an example, when the drying process is performed with the drying condition improved or optimized for the third emission layer 223 not including the quantum dots, the first and second emission layers 221 and 222 including the quantum dots may have severe thickness non-uniformity due to the material for forming the emission layer being severely piled up on the outer portion due to the coffee-ring effect.

To prevent or reduce the likelihood of this phenomenon occurring, in the display apparatus according to one or more embodiments, a trench structure TRC may be formed in a portion of the lateral surface of the bank layer 120 facing the opening OP. In one or more embodiments, the trench structures TRC may be formed in only the lateral surfaces of the bank layer 120 adjacent to the first emission layer 221 and the second emission layer 222, and may not be formed in the lateral surfaces of the bank layer 120 adjacent to the third emission layer 223. Because the bank layer 120 defines the first to third openings 120OP1, 120OP2, and 120OP3, the bank layer 120 may include the lateral surface facing the first opening 120OP1, the lateral surface facing the second opening 120OP2, and the lateral surface facing the third opening 120OP3. In the display apparatus 1 shown in FIG. 5, the trenches TRC may be formed in only the lateral surfaces facing the first opening 120OP1 and the second opening 120OP2 among the lateral surfaces of the bank layer 120.

The trench TRC may include a 1-1 trench T11 and a 1-2 trench T12 each facing the first emission layer 221, and a 2-1 trench T21 and a 2-2 trench T22 each facing the second emission layer 222. For example, the 1-1 trench T11 may be located in the lateral surface of the bank layer 120 facing the first opening 120OP1 arranged between the third pixel PX3 and the first pixel PX1, and the 1-2 trench T12 may be located in the lateral surface of the bank layer 120 facing the first opening 120OP1 arranged between the first pixel PX1 and the second pixel PX2. The 2-1 trench T21 may be located in the lateral surface of the bank layer 120 facing the second opening 120OP2 arranged between the first pixel PX1 and the second pixel PX2, and the 2-2 trench T22 may be located in the lateral surface of the bank layer 120 facing the second opening 120OP2 arranged between the second pixel PX2 and the third pixel PX3.

The trench TRC is a portion in which a portion of the lateral surface of the bank layer 120 is depressed, and may be thinner than other portions of the bank layer 120. The trench TRC may have a shape dug or etched in a direction opposite to a direction facing the opening OP compared to the flat lateral surface of the bank layer 120. The trench TRC may be located in the lower portion of the bank layer 120 to expose the upper surface of the pixel electrode 210. The trench TRC may expose an outer area that is further than the area of the upper surface of the pixel electrode 210 exposed by the opening OP. That is, the first and second pixel electrodes 211 and 212 overlapping the trench TRC and the opening OP may expose a wider upper surface than does the third pixel electrode 213 overlapping only the opening OP. The trench TRC may be filled with the intermediate layer, for example, the corresponding emission layer(s) 220.

The width of the trench TRC may be about ¼^{th} to about ⅓^{rd} of the width of the lower surface of the bank layer 120 in the case where the trench TRC is not formed. As an example, the width of the lower surface of the bank layer 120 arranged between the 1-2 trench T12 and the 2-1 trench T21 may be 1 to 2 times the width of the trench TRC. For example, the width of the trench TRC may be about 200 Å to about 400 Å. The thickness of the trench TRC may be about 300 Å to about 1000 Å. When the thickness of the trench TRC is equal to or greater than 1000 Å, it may be difficult to remove a sacrificial layer, which will be described later, after forming the sacrificial layer. When the thickness of the trench TRC is equal to or less than 300 Å, an intended aspect of the trench TRC may not be sufficiently achieved.

As described above, when the drying process of the emission layer 220 is improved or optimized for the drying condition of the third emission layer 223, because the drying condition of the first emission layer 221 and the second emission layer 222 including the quantum dots is different, the outer portion accumulation phenomenon may accelerate and the thickness non-uniformity may worsen. In this case, as in the display apparatus 1 according to one or more embodiments, in the case where the trench TRC is formed in the lateral surface of the bank layer 120 facing the first opening 120OP1 and the second opening 120OP2, the outer portion accumulation phenomenon is reduced or prevented, and thus, the thickness uniformity of the first and second emission layers 221 and 222 may be improved. For example, in the case where the trench TRC is formed in the lower portion of the bank layer 120, a portion of the lateral surface of the bank layer 120 is depressed, and thus, a convective flow may be reduced or prevented. In other words, because the flow of solutes that are pushed out from the inside to the outside due to the difference in evaporation rate is interrupted, the phenomenon of the material for forming the emission layer being piled up on the outside may be resolved. Accordingly, not only the third emission layer 223, but also the first and second emission layers 221 and 222, may have a substantially uniform profile after the drying process. The emission efficiency and the lifespan efficiency of both the first and second light-emitting diodes LED1 and LED2 including the quantum-dot emission layer, and the third light-emitting diode LED3 including the organic emission layer, may be improved.

In addition, the trench TRC may expose the upper surface of the pixel electrode 210, and the end of the pixel electrode 210 may be covered by the bank layer 120. As described above, in one or more embodiments, the pixel electrode 210 may have a three-layered structure of ITO/Ag/ITO. When the edges of the pixel electrode 210 having the above structure are not cladded, silver Ag may be eluted to potentially cause defects. Accordingly, because the trench TRC exposes only a portion of the pixel electrode 210, and the edges of the pixel electrode 210 is cladded by the bank layer 120, defective elution of Ag may be reduced or prevented.

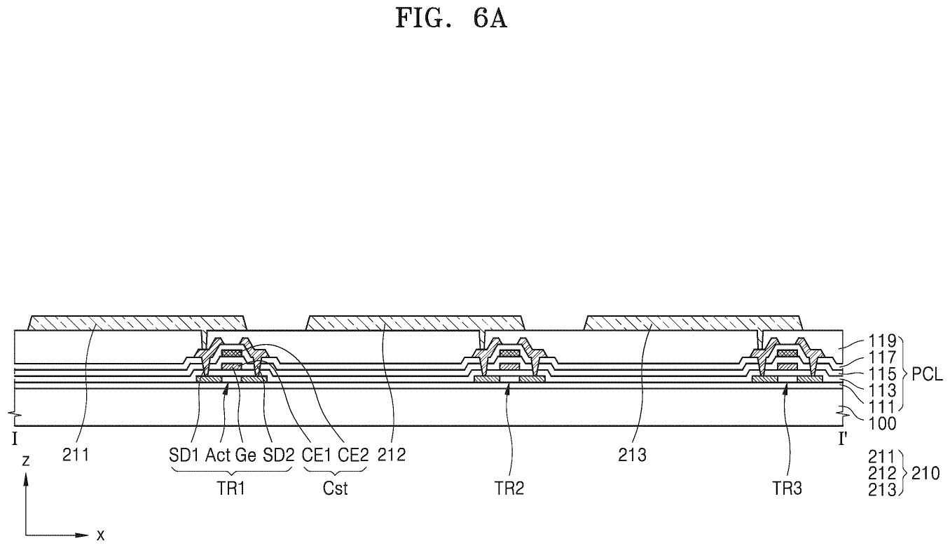

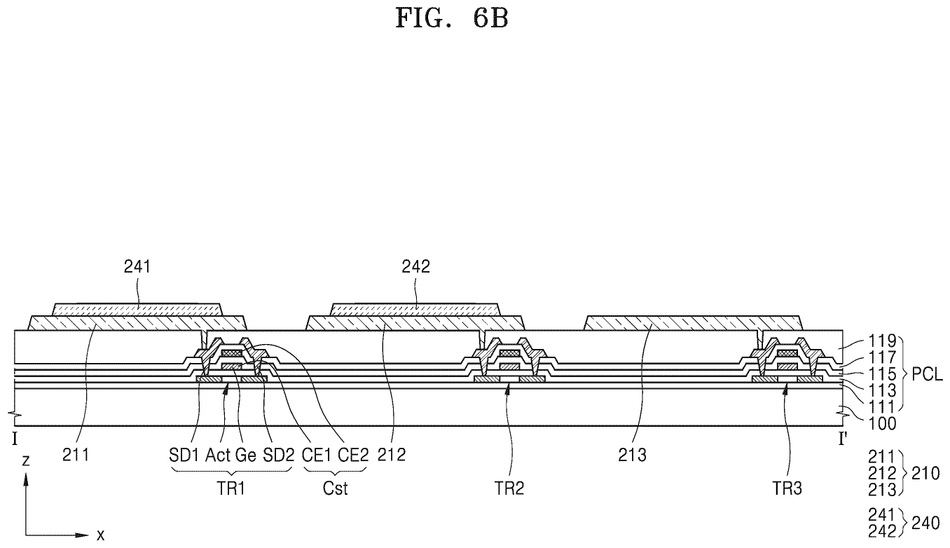

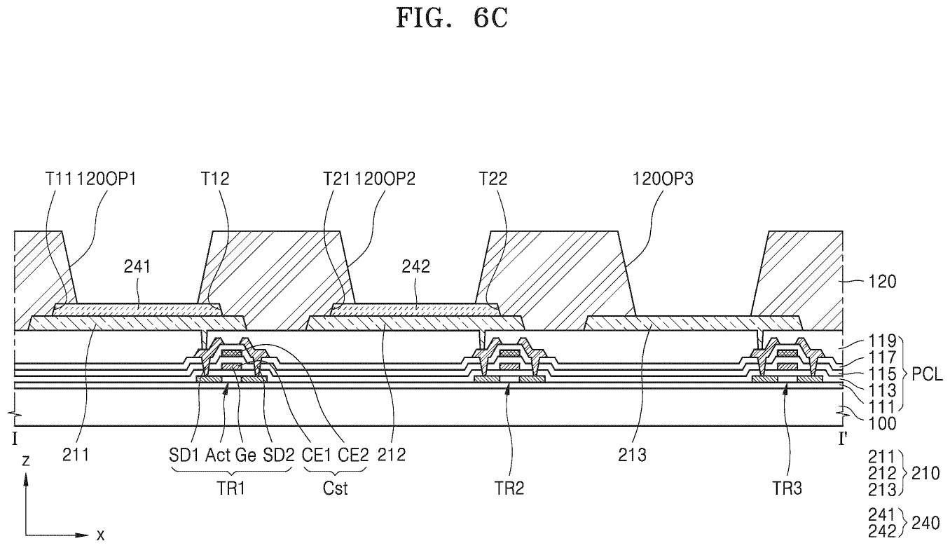

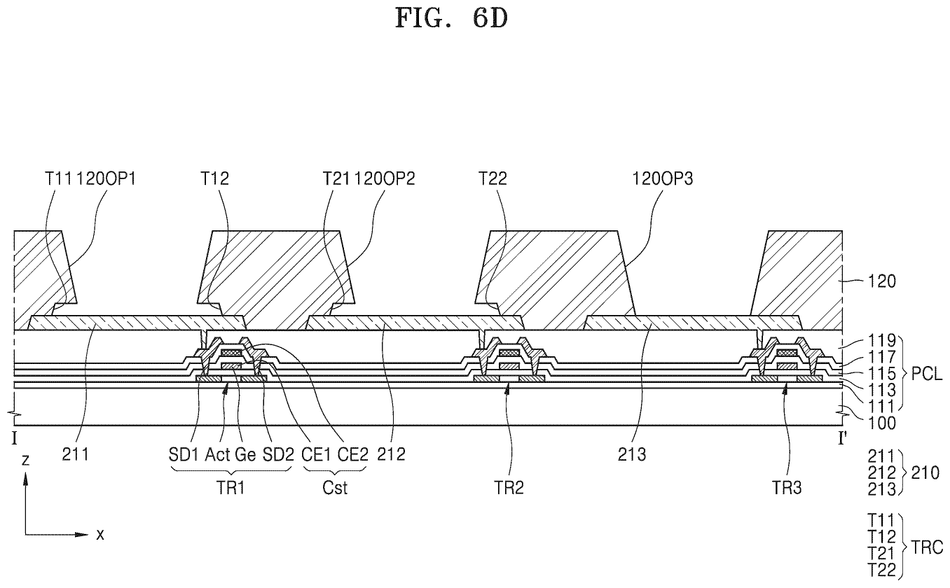

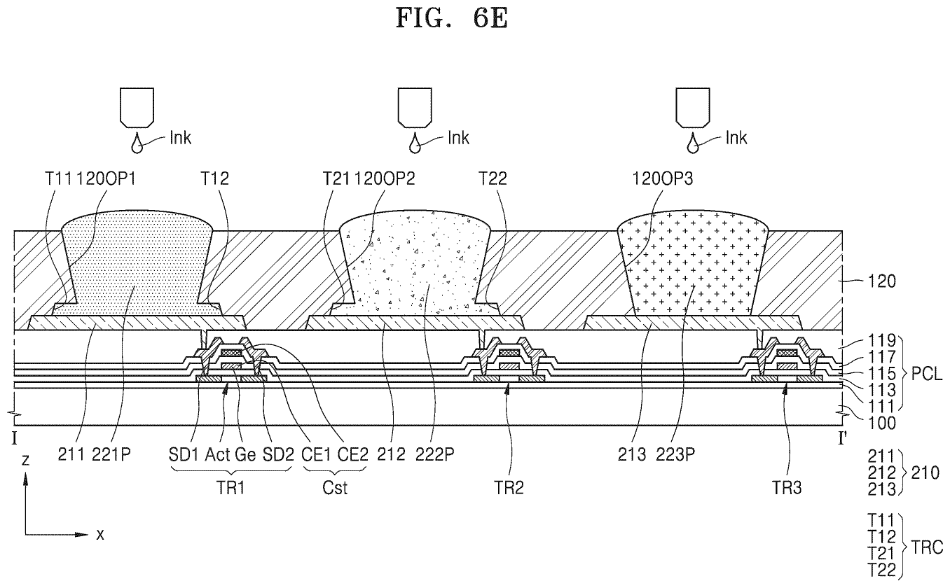

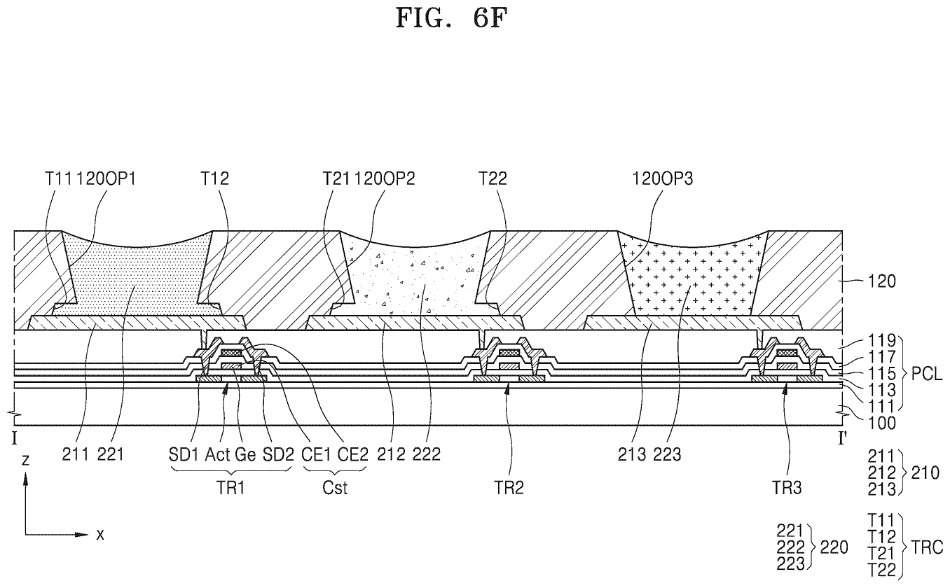

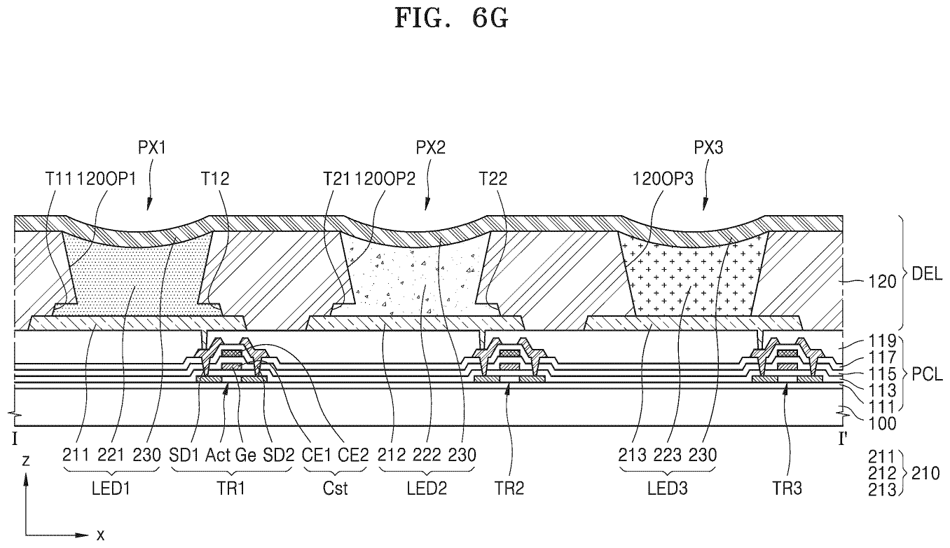

FIGS. 6A to 6G are schematic cross-sectional views showing a process of manufacturing a display apparatus according to one or more embodiments. FIGS. 6A to 6G are cross-sectional views of the display apparatus, taken along the line I-I′ of the display apparatus of FIG. 4 according to the manufacturing process.

Referring to FIG. 6A, the pixel circuit layer PCL may be formed on the substrate 100, and the pixel electrode 210 may be formed on the pixel circuit layer PCL.

The pixel circuit layer PCL may include the first to third transistors TR1, TR2, and TR3. The first to third pixel electrodes 211, 212, and 213 may be formed to be apart from each other on the planarization layer 119. The first pixel electrode 211 may correspond to the first pixel PX1 (see FIG. 4) configured to emit red light, the second pixel electrode 212 may correspond to the second pixel PX2 (see FIG. 4) configured to emit green light, and the third pixel electrode 213 may correspond to the third pixel PX3 (see FIG. 4) configured to emit blue light. The first pixel electrode 211 may be electrically connected to the first transistor TR1, the second pixel electrode 212 may be electrically connected to the second transistor TR2, and the third pixel electrode 213 may be electrically connected to the third transistor TR3.

Referring to FIG. 6B, a sacrificial layer 240 may be formed on the first pixel electrode 211 and the second pixel electrode 212. The sacrificial layer 240 is located to form the trench TRC (see FIG. 5), and may not be located on the third pixel electrode 213. That is, the sacrificial layer 240 may include a first sacrificial layer 241 formed on the first pixel electrode 211, and a second sacrificial layer 242 formed on the second pixel electrode 212.

The sacrificial layer 240 may include a material that is removed by water, or a developer, such as a tetramethylammonium hydroxide (TMAH) solution. In one or more embodiments, the sacrificial layer 240 may include at least one of tungsten oxide (WOₓ) or molybdenum oxide (MoOₓ). As described later, because the sacrificial layer 240 includes at least one of water-soluble tungsten oxide (WOₓ) or molybdenum oxide (MoOₓ), in the subsequent cleaning process, the sacrificial layer 240 may be removed by ultrapure water (DI water) in a subsequent cleaning process.

In one or more embodiments, the area of the sacrificial layer 240 in a plan view may be less than the area of the pixel electrode 210. That is, because the width of the sacrificial layer 240 may be less than the width of the pixel electrode 210, the end of the pixel electrode 210 may be covered by the bank layer 120 (see FIG. 6C) described below. As described above, the pixel electrode 210 may have a structure of ITO/Ag/ITO, and the purpose of this covering of the pixel electrode 210 is to reduce or prevent silver elution by cladding the end of the pixel electrode 210 with the bank layer 120. In addition, in one or more embodiments, the thickness of the sacrificial layer 240 may be about 300 Å to about 1000 Å. When the sacrificial layer 240 is formed to a thickness of about 1000 Å or more, it may be difficult to remove the sacrificial layer 240. When the thickness of the sacrificial layer 240 is about 300 Å or less, an intended aspect of the trench TRC (see FIG. 5) may not be sufficiently achieved.

Referring to FIG. 6C, the bank layer 120 may be formed on the pixel circuit layer PCL. The bank layer 120 may be formed to cover the ends of the pixel electrode 210 and the sacrificial layer 240. The bank layer 120 may be formed by forming an inorganic insulating material layer or an organic insulating material layer, and by then patterning the inorganic insulating material layer or the organic insulating material layer to form the first to third openings 120OP1, 120OP2, and 120OP3 respectively exposing the central portions of the first to third pixel electrodes 211, 212, and 213. In one or more embodiments, the bank layer 120 may include silicon oxide (SiOₓ), silicon nitride (SiNₓ), silicon oxynitride (SiON), and the like. In one or more embodiments, the bank layer 120 may include an epoxy-based polymer, an acrylic-based polymer, or a mixture thereof. In one or more other embodiments, the bank layer 120 may include a photoresist, that is, photosensitive resin.

Referring to FIG. 6D, the sacrificial layer 240 may be removed through the cleaning process. As described above, when the sacrificial layer 240 includes at least one of tungsten oxide (WOₓ) or molybdenum oxide (MoOₓ), the sacrificial layer 240 has water solubility and may be removed through the cleaning process with ultrapure water (DI water).

Because the ends of the sacrificial layer 240 are covered by the bank layer 120, when the sacrificial layer 240 is removed through the cleaning process, the trench TRC may be formed in the lateral surface of the bank layer 120. Because the sacrificial layer 240 is formed on only the first pixel electrode 211 and the second pixel electrode 212, the trenches TRC may be formed in the lateral surfaces of the bank layer 120 facing the first opening 120OP1 and the second opening 120OP2. That is, the trench TRC may include the 1-1 trench T11 and the 1-2 trench T12 respectively formed in the lateral surfaces of the bank layer 120 facing the first opening 120OP1, and the 2-1 trench T21 and the 2-2 trench T22 respectively formed in the lateral surfaces of the bank layer 120 facing the second opening 120OP2.

Referring to FIG. 6E, by discharging ink including an emission material, a material 221P for forming the first emission layer may be formed on the first pixel electrode 211, a material 222P for forming the second emission layer may be formed on the second pixel electrode 212, and a material 223P for forming the third emission layer may be formed on the third pixel electrode 213. The material 221P for forming the first emission layer, and the material 222P for forming the second emission layer, may include an emission material including quantum dots, and the material 223P for forming the third emission layer may include an emission material including only an organic material.

In one or more embodiments, the material 221P for forming the first emission layer, the material 222P for forming the second emission layer, and the material 223P for forming the third emission layer may be formed by an inkjet printing process. The materials 221P, 222P, and 223P for forming the first to third emission layers may have a convex shape whose central portion is relatively thick by accounting for surface tension and the volume shrinkage after drying. However, the present disclosure is not limited thereto. In one or more other embodiments, the materials 221P, 222P, and 223P for forming the first to third emission layers may have a flat shape or a concave shape according to the sprayed amount of the ink including the emission material.

Referring to FIG. 6F, the first to third emission layers 221, 222, and 223 may be formed by drying the materials 221P, 222P, and 223P for forming the first to third emission layers. As described above, a solvent of ink including the emission material evaporates, and due to the coffee-ring effect, the emission layer 220 may have a concave shape that becomes thicker from the center to the outside.

In one or more embodiments, the drying process of the materials 221P, 222P, and 223P for forming the first to third emission layers may be performed with a drying condition improved or optimized for the third emission layer 223. Because the third emission layer 223 does not include quantum dots and the first and second emission layers 221 and 222 include quantum dots, when the drying process is performed with a condition improved or optimized for the third emission layer 223, drying deviations may occur due to a difference in the materials. That is, the thickening of the outer portion of the first and second emission layers 221 and 222 becomes severe, and thus, uniformity in the thickness may be lowered.

In contrast, in the display apparatus according to one or more embodiments, because the trenches TRC are formed in the lateral surfaces of the bank layer 120 adjacent to the first and second emission layers 221 and 222, the trenches TRC may reduce or prevent a convective flow of the materials 221P and 222P for forming the first and second emission layers due to the drying process. Accordingly, the coffee-ring effect and the outer accumulation phenomenon weaken in the first and second emission layers 221 and 222, and thus, the thickness uniformity of the first and second emission layers 221 and 222 may be improved. Accordingly, the emission efficiency and the lifespan efficiency of the first and second light-emitting diodes LED1 and LED2 including the first and second emission layers 221 and 222 may be improved.

Referring to FIG. 6G, the opposite electrode 230 may be formed on the first to third emission layers 221, 222, and 223, and the bank layer 120. The opposite electrode 230 may be integrally formed on the entire surface of the substrate 100. Accordingly, the first pixel electrode 211, the first emission layer 221, and the opposite electrode 230 may constitute the first light-emitting diode LED1. Further, the second pixel electrode 212, the second emission layer 222, and the opposite electrode 230 may constitute the second light-emitting diode LED2. Also, the third pixel electrode 213, the third emission layer 223, and the opposite electrode 230 may constitute the third light-emitting diode LED3.

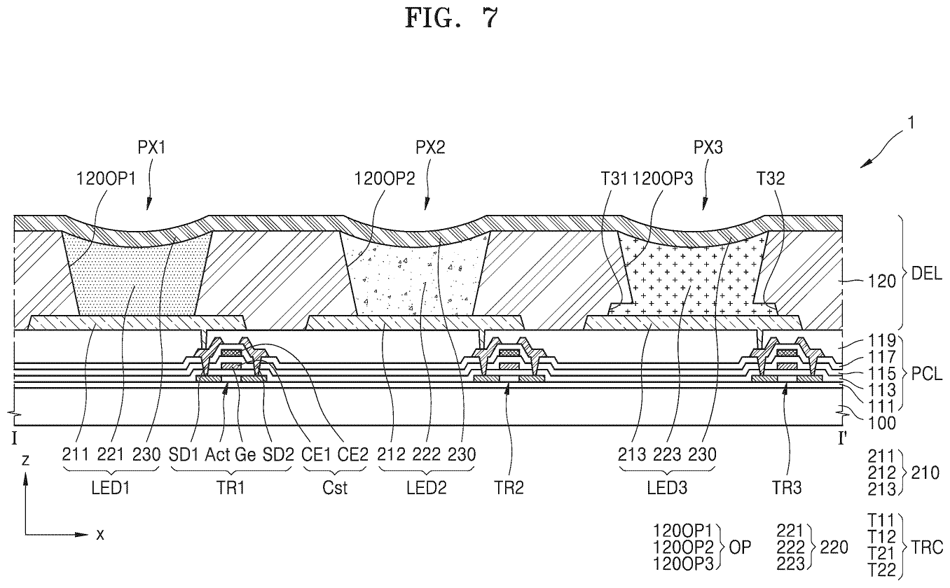

FIG. 7 is a schematic cross-sectional view of a display apparatus according to one or more other embodiments. Referring to FIG. 7, the other characteristics except for the characteristic of the trench TRC are the same as those described with reference to FIGS. 4 and 5. Same reference numerals among elements of FIG. 7 are replaced with those previously described with reference to FIGS. 4 and 5, and differences are mainly described below.

Referring to FIG. 7, the first and second light-emitting diodes LED1 and LED2 may be quantum-dot light-emitting elements, and the third light-emitting diode LED3 may be an organic light-emitting element. That is, the first and second emission layers 221 and 222 may include the emission material including quantum dots, and the third emission layer 223 may include only the organic material. Accordingly, the display apparatus 1 of FIG. 7 may have not only suitable emission characteristics by improving color purity and color reproduction, but also may implement a long lifespan.

However, as described above, because the emission layer including the quantum dots and the emission layer including only the organic material are different from each other in their materials, and thus, required drying conditions are different from each other, when the drying process is performed with the drying condition improved or optimized for one side, the other side may have a lowered thickness uniformity due to the coffee-ring effect. As an example, when the drying process is performed with the drying condition improved or optimized for the first and second emission layer 221 and 222 including the quantum dots, the third emission layer 223 not including the quantum dots may have severe thickness non-uniformity due to the material for forming the emission layer being severely piled up on the outer portion due to the coffee-ring effect.

To reduce or prevent the likelihood of this phenomenon occurring, in the display apparatus according to one or more embodiments, a trench structure TRC may be formed in a portion of the lateral surface of the bank layer 120 facing the opening OP. In one or more embodiments, the trench structures TRC may be formed in only the lateral surfaces of the bank layer 120 adjacent to the third emission layer 223, and may not be formed in the lateral surfaces of the bank layer 120 adjacent to the first and second emission layer 221 and 222. Because the bank layer 120 defines the first to third openings 120OP1, 120OP2, and 120OP3, the bank layer 120 may include the lateral surface facing the first opening 120OP1, the lateral surface facing the second opening 120OP2, and the lateral surface facing the third opening 120OP3. In the display apparatus 1 shown in FIG. 7, the trenches TRC may be formed in only the lateral surfaces facing the third opening 120OP3 among the lateral surfaces of the bank layer 120.

That is, the trench TRC may include a 3-1 trench T31 and a 3-2 trench T32 each facing the third emission layer 223. For example, the 3-1 trench T31 may be located in the lateral surface of the bank layer 120 facing the third opening 120OP3 arranged between the second pixel PX2 and the third pixel PX3, and the 3-2 trench T32 may be located in the lateral surface of the bank layer 120 facing the third opening 120OP3 arranged between the third pixel PX3 and another first pixel PX1. However, the structures and the corresponding characteristics of the 3-1 trench T31 and the 3-2 trench T32 shown in FIG. 7 may be the same as the trench TRC of FIG. 5.

Accordingly, when the drying process of the emission layer 220 is improved or optimized for the drying conditions of the first and second emission layers 221 and 222, because the third emission layer 223 does not include the quantum dots, the drying condition is different, and the outer accumulation phenomenon accelerates, resulting in severe thickness non-uniformity. In this case, as in the display apparatus 1 according to one or more embodiments, when the trench TRC is formed in the lateral surface of the bank layer 120 facing the third opening 120OP3, the outer accumulation phenomenon is reduced or prevented, and thus, the thickness uniformity of the third emission layer 223 may be improved. As a result, because not only the first and second emission layers 221 and 222, but also the third emission layer 223, may have a substantially uniform profile after drying, the emission efficiencies and the lifespan efficiencies of all of the first to third light-emitting diodes LED1, LED2, and LED3 may be improved.

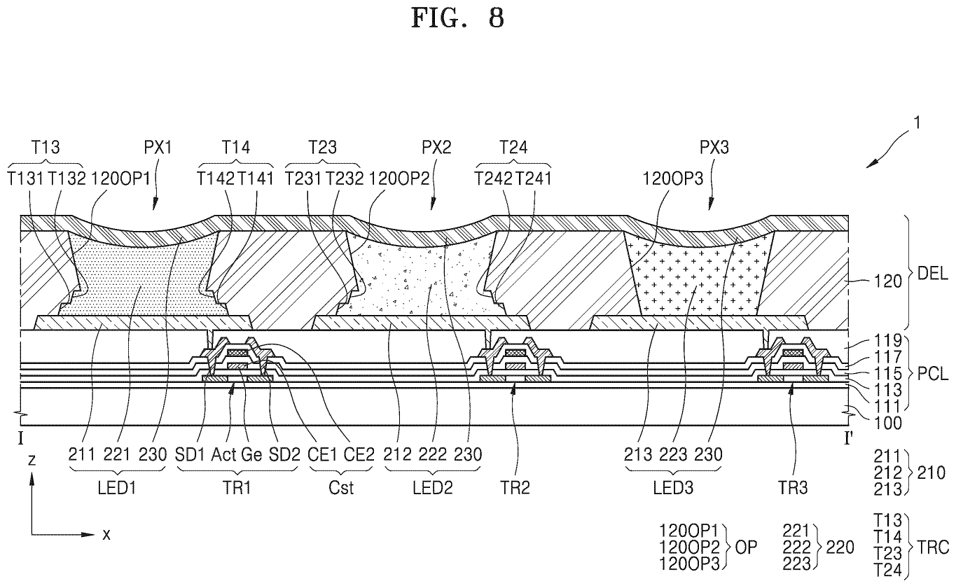

FIG. 8 is a schematic cross-sectional view of a display apparatus according to one or more other embodiments. Referring to FIG. 8, the other characteristics except for the characteristic of the trench TRC are the same as those described with reference to FIGS. 4 and 5. Same reference numerals among elements of FIG. 8 are replaced with those previously described with reference to FIGS. 4 and 5, and differences are mainly described below.

Referring to FIG. 8, the first and second light-emitting diodes LED1 and LED2 may be quantum-dot light-emitting elements, and the third light-emitting diode LED3 may be an organic light-emitting element. That is, the first and second emission layers 221 and 222 may include the emission material including quantum dots, and the third emission layer 223 may include the emission material including only the organic material. Accordingly, the display apparatus 1 of FIG. 8 may have not only suitable emission characteristics by improving color purity and color reproduction, but also may implement a long lifespan.

However, as described above, because the emission layer including the quantum dots and the emission layer including only the organic material are different from each other in their materials, and thus, required drying conditions are different from each other, when the drying process is performed with the drying condition improved or optimized for one side, the other side may have a lowered thickness uniformity due to the coffee-ring effect. As an example, when the drying process is performed with the drying condition improved or optimized for the third emission layer 223 not including the quantum dots, the first and second emission layers 221 and 222 including the quantum dots may have severe thickness non-uniformity due to the material for forming the emission layer being severely piled up on the outer portion due to the coffee-ring effect.

To reduce or prevent the likelihood of this phenomenon occurring, in the display apparatus according to one or more embodiments, the trench structure TRC may be formed in only a portion of the lateral surface of the bank layer 120 facing the opening OP. In one or more embodiments, the trench structures TRC may be formed in only the lateral surfaces of the bank layer 120 adjacent to the first emission layer 221 and the second emission layer 222, and may not be formed in the lateral surfaces of the bank layer 120 adjacent to the third emission layer 223. In the display apparatus 1 shown in FIG. 8, the trenches TRC may be formed in only the lateral surfaces facing the first opening 120OP1 and the second opening 120OP2 among the lateral surfaces of the bank layer 120.

The trench TRC may include a 1-1 trench T13 and a 1-2 trench T14 each facing the first emission layer 221, and a 2-1 trench T23 and a 2-2 trench T24 each facing the second emission layer 222. For example, the 1-1 trench T13 may be located in the lateral surface of the bank layer 120 facing the first opening 120OP1 arranged between another third pixel PX3 and the first pixel PX1, and the 1-2 trench T14 may be located in the lateral surface of the bank layer 120 facing the first opening 120OP1 arranged between the first pixel PX1 and the second pixel PX2. The 2-1 trench T23 may be located in the lateral surface of the bank layer 120 facing the second opening 120OP2 arranged between the first pixel PX1 and the second pixel PX2, and the 2-2 trench T24 may be located in the lateral surface of the bank layer 120 facing the second opening 120OP2 arranged between the second pixel PX2 and the third pixel PX3.

The trench TRC may include a double trench structure. For example, the trench TRC is a portion in which a portion of the lateral surface of the bank layer 120 is depressed, and may be thinner than other portions of the bank layer 120. In this case, the trench TRC may include a lower trench in which a portion of the lateral surface of the bank layer 120 is more deeply depressed, and an upper trench in which a portion of the lateral surface of the bank layer 120 is less deeply depressed. The lateral surface of the bank layer 120 may include a reverse-stepped shape due to the trench TRC formed in the double trench structure.

As an example, the 1-1 trench T13 may include a 1-1 lower trench T131 in which a portion of the lateral surface of the bank layer 120 is more deeply depressed, and a 1-1 upper trench T132 in which a portion of the lateral surface of the bank layer 120 is less deeply depressed. Likewise, the 1-2 trench T14 may include a 1-2 lower trench T141 in which a portion of the lateral surface of the bank layer 120 is more deeply depressed, and a 1-2 upper trench T142 in which a portion of the lateral surface of the bank layer 120 is less deeply depressed. The 2-1 trench T23 may include a 2-1 lower trench T231 that is more deeply depressed, and a 2-1 upper trench T232 that is less deeply depressed, and the 2-2 trench T23 may include a 2-2 lower trench T241 that is more deeply depressed, and a 2-2 upper trench T242 that is less deeply depressed.

Because the trench structures overlap each other in two layers, the thickness of the trench TRC of the display apparatus 1 shown in FIG. 8 may be about 600 Å to about 2000 Å. In addition, like the trench TRC in FIG. 5, the width of the trench TRC may be about ¼^{th} to about ⅓^{rd} of the width of the lower surface of the bank layer 120 in the case where the trench TRC is not formed.

As described with reference to FIGS. 6A and 6G, the trench TRC may be formed through the sacrificial layer 240 (see FIG. 6B). Accordingly, to form the trench TRC having the double trench structure shown in FIG. 8, a lower sacrificial layer and an upper sacrificial layer respectively having different areas may be formed on the pixel electrode 210. In this case, the lower sacrificial layer may have an area that is less than the pixel electrode 210 in a plan view, and the upper sacrificial layer may have an area that is less than the lower sacrificial layer in a plan view. Then, when the lower sacrificial layer and the upper sacrificial layer are removed through the cleaning process, the lower trenches T131, T141, T231, and T241, and the upper trenches T132, T142, T232, and T242 may be formed as in FIG. 8.

Because, when the drying process of the emission layer 220 is improved or optimized for the drying condition of the third emission layer 223, the drying condition of the first emission layer 221 and the second emission layer 222 including the quantum dots is different, the outer portion accumulation phenomenon may accelerate, and the thickness non-uniformity may worsen. In this case, like the display apparatus 1 shown in FIG. 8, in the case where the trench TRC is formed in the double trench structure on the lateral surface of the bank layer 120 facing the first opening 120OP1 and the second opening 120OP2, an aspect in reducing or preventing the outer portion accumulation phenomenon increases, and thus, the thickness uniformity of the first and second emission layers 221 and 222 may be further improved. For example, in the case where the double trench structure is formed in the lower portion of the bank layer 120, because a step difference occurs even in the depressed portion of the lateral surface of the bank layer 120, a convective flow may be further hindered. In other words, because the flow of solutes that are pushed out from the inside to the outside due to the difference in evaporation rate is interrupted twice, the phenomenon of the material for forming the emission layer being piled up on the outside may be more effectively resolved.

Accordingly, not only the third emission layer 223 but also the first and second emission layers 221 and 222 may have a more uniform profile after the drying process. The emission efficiency and the lifespan efficiency of both the first and second light-emitting diodes LED1 and LED2 including the quantum-dot emission layer and the third light-emitting diode LED3 including the organic emission layer may be improved even more.

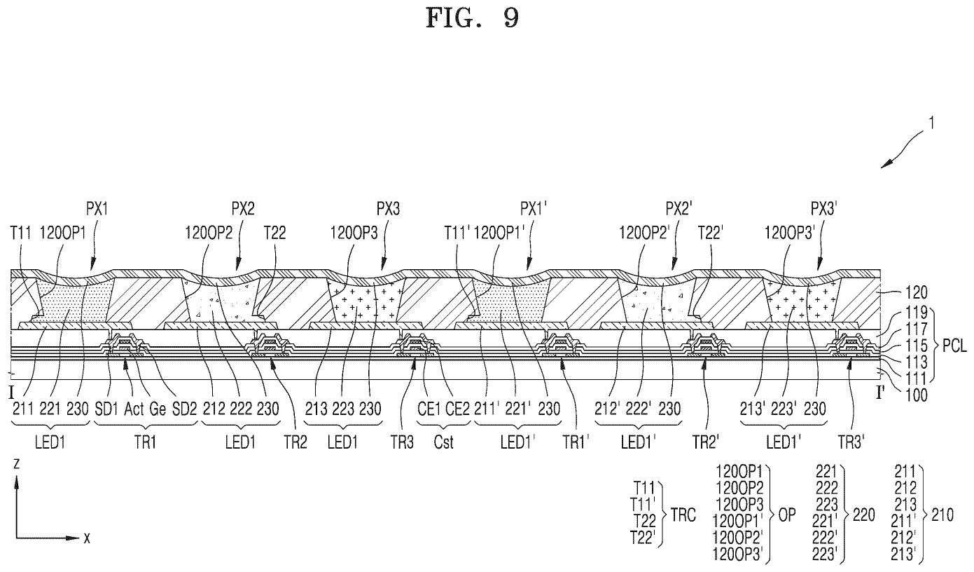

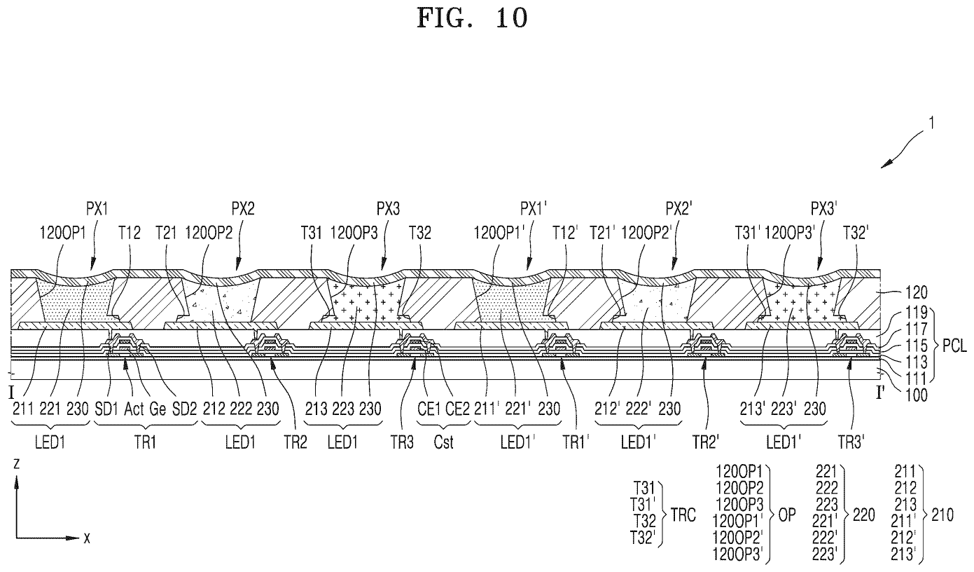

FIG. 9 is a schematic cross-sectional view of a display apparatus according to one or more other embodiments, and FIG. 10 is a schematic cross-sectional view of a display apparatus according to one or more other embodiments. FIGS. 9 and 10 are schematic cross-sectional views of a region wider than a region A of FIG. 4.

Referring to FIGS. 9 and 10, the plurality of pixels PX (see FIG. 1) may include first pixels PX1 and PX1′, second pixels PX2 and PX2′, and third pixels PX3 and PX3′. The first pixels PX1 and PX1′ may be configured to emit red light, the second pixels PX2 and PX2′ may be configured to emit green light, and the third pixels PX3 and PX3′ may be configured to emit blue light.

First light-emitting diodes LED1 and LED1′ and second light-emitting diodes LED2 and LED2′ may be quantum-dot light-emitting elements, and third light-emitting diodes LED3 and LED3′ may be organic light-emitting elements. That is, first and second emission layers 221, 221′, 222, and 222′ may include the emission material including quantum dots, and third emission layers 223 and 223′ may include an emission material including only the organic material. Accordingly, the display apparatus 1 of FIG. 7 may have not only suitable emission characteristics by improving color purity and color reproduction, but also may implement a long lifespan.

Because a material of the emission layer including the quantum dots and a material of the emission layer including only the organic material are different from each other, drying deviations may occur. For example, the drying speed of the third emission layers 223 and 223′ including only the organic material may be faster than the drying speed of the first and second emission layers 221, 221′, 222, and 222′. That is, because the drying speed of the third emission layers 223 and 223′ is faster than the drying speed of the first and second emission layers 221, 221′, 222, and 222′, the edge portions of the first and second emission layers 221, 221′, 222, and 222′ adjacent to the third emission layers 223 and 223′ may evaporate first.

In this case, as described above, within the material for forming the emission layer, a convective flow may occur due to differences in evaporation rates during the drying process. When a portion of the material for forming the first emission layer adjacent to the third emission layers 223 and 223′ evaporates first, liquid inside the material for forming the first emission layer may flow to the edge adjacent to the third emission layers 223 and 223′. Accordingly, in the material for forming the first emission layer, solutes which have moved from the inside accumulate at the edges adjacent to the third emission layers 223 and 223′, and the solutes may continue to accumulate as the liquid continues to evaporate. That is, due to the differences in evaporation rates, each of the first emission layers 221 and 221′ and the second emission layers 222 and 222′ may have a non-uniform profile in which the edges adjacent to the third emission layers 223 and 223′ are high and the edges away from the third emission layers 223 and 223′ are low.

To reduce or prevent the likelihood of this phenomenon occurring, in the display apparatus 1 shown in FIGS. 9 and 10, the trench structure TRC may be formed in only a portion of the lateral surface of the bank layer 120 facing the opening OP. For example, the trench TRC may be formed in an asymmetrical trench structure in which the trench TRC is formed in only one of the lateral surfaces of the bank layer 120 facing the each opening OP.

First, referring to FIG. 9, the trench TRC may be formed in only the lateral surfaces of the bank layer 120 adjacent to the first emission layers 221 and 221′ and the second emission layers 222 and 222′, and may not be formed in the lateral surfaces of the bank layer 120 adjacent to the third emission layers 223 and 223′. However, in one or more embodiments, the trench TRC may be formed in only the lateral surfaces of the bank layer 120 adjacent to the third openings 120OP3 and 120OP3′ among the lateral surfaces of the bank layer 120 facing the first opening 120OP1 and 120OP1′ and the second openings 120OP2 and 120OP2′. That is, the trench TRC may be formed in only regions in which drying speeds are fast among the lateral surfaces of the bank layer 120 facing the first opening 120OP1 and 120OP1′ and the second openings 120OP2 and 120OP2′.

As an example, the trench TRC may include only 1-1 trenches T11 and T11′ and 2-2 trenches T22 and T22′. For example, the 1-1 trenches T11 and T11′ may be located in only the lateral surfaces adjacent to the third openings 120OP3 and 120OP3′ among the lateral surfaces of the bank layer 120 facing the first openings 120OP1 and 120OP1′. The 2-2 trenches T22 and T22′ may be located in only the lateral surfaces adjacent to the third openings 120OP3 and 120OP3′ among the lateral surfaces of the bank layer 120 facing the second openings 120OP2 and 120OP2′. In this case, the shapes and the corresponding characteristics of the 1-1 trenches T11 and T11′ and the 2-2 trenches T22 and T22′ may be similar to the trench TRC of FIG. 5.

As described above, because, when the process of the emission layer 220 is improved or optimized for the drying condition of the third emission layers 223 and 223′, the drying condition of the first emission layers 221 and 221′ and the second emission layers 222 and 222′ including the quantum dots is different, the drying deviations may become relatively severe. As the first emission layers 221 and 221′ and the second emission layers 222 and 222′ are adjacent to the third emission layers 223 and 223′, the non-uniformity of the profile that the thickness is high may become more severe. In contrast, when the 1-1 trenches T11 and T11′ and the 2-2 trenches T22 and T22′ are formed as in the display apparatus 1 of FIG. 9, a convective flow of the material for forming the emission layer is hindered, and the degree of uniformity in the thickness of the first emission layers 221 and 221′ and the second emission layers 222 and 222′ may be improved.

Next, referring to FIG. 10, the trench TRC may be formed in the lateral surfaces of the bank layer 120 adjacent to the third emission layers 223 and 223′, may be formed in only a portion of the lateral surfaces of the bank layer 120 adjacent to the first emission layers 221 and 221′, and may be formed in only a portion of the lateral surfaces of the bank layer 120 adjacent to the second emission layers 222 and 222′. The trench TRC may be formed in only the lateral surfaces of the bank layer 120 away from the third openings 120OP3 and 120OP3′ among the lateral surfaces of the bank layer 120 facing the first opening 120OP1 and 120OP1′ and the second openings 120OP2 and 120OP2′. That is, the trench TRC may be formed in only the region in which the drying speed is slow and the lateral surfaces of the bank layer 120 facing the third openings 120OP3 and 120OP3′ among the lateral surfaces of the bank layer 120 facing the first opening 120OP1 and 120OP1′ and the second openings 120OP2 and 120OP2′.

As an example, the trench TRC may include 1-2 trenches T12 and T12′, 2-1 trenches T21 and T21′, 3-1 trenches T31 and T31′, and 3-2 trenches T32 and T32′. For example, the 1-2 trenches T12 and T12′ may be located in only the lateral surfaces away from the third openings 120OP3 and 120OP3′ among the lateral surfaces of the bank layer 120 facing the first openings 120OP1 and 120OP1′. The 2-1 trenches T21 and T21′ may be located in only the lateral surfaces away from the third openings 120OP3 and 120OP3′ among the lateral surfaces of the bank layer 120 facing the second openings 120OP2 and 120OP2′.

In addition, the 3-1 trenches T31 and T31′ may be located in the lateral surfaces of the bank layer 120 facing the third opening 120OP3 arranged between respective ones of the second pixels PX2 and PX2′ and the third pixels PX3 and PX3′. The 3-2 trenches T32 and T32′ may be located in the lateral surfaces of the bank layer 120 facing the third opening 120OP3 arranged between respective ones of the third pixels PX3 and PX3′ and the first pixels PX1 and PX1′. In this case, the structures and the corresponding characteristics of the 1-2 trenches T12 and T12′, the 2-1 trenches T21 and T21′, the 3-1 trenches T31 and T31′, and the 3-2 trenches T32 and T32′ may be similar to the trench TRC of FIG. 5.

As described above, when the process of the emission layer 220 is improved or optimized for the drying conditions of the first emission layers 221 and 221′ and the second emission layers 222 and 222′, the third emission layers 223 and 223′ do not include the quantum dots, and thus, the drying condition is different and drying deviations may become more severe. As the first emission layers 221 and 221′ and the second emission layers 222 and 222′ are adjacent to the third emission layers 223 and 223′, the non-uniformity of the profile that the thickness is high may become more severe. Likewise, in the third emission layers 223 and 223, the outer portion accumulation becomes severe, and thus, the non-uniformity in the thickness may become severe. In contrast, when the 1-2 trenches T12 and T12′, the 2-1 trenches T21 and T21′, the 3-1 trenches T31 and T31′, and the 3-2 trenches T32 and T32′ are formed as in the display apparatus 1 of FIG. 10, a convective flow of the material for forming the emission layer is hindered, and the uniformity in the thickness of the first emission layers 221 and 221′, the second emission layers 222 and 222′, and the third emission layers 223 and 223′ may be improved.

As a result, in the display apparatus 1 shown in FIGS. 9 and 10, because all of the first emission layers 221 and 221′, the second emission layers 222 and 222′, and the third emission layers 223 and 223′ may have a substantially uniform profile after drying, the emission efficiencies and the lifespan efficiencies of the first to third light-emitting diodes LED1, LED2, and LED3 may be improved.

In the display apparatus according to one or more embodiments, because the trench structure is employed in the bank layer, the emission efficiency and the lifespan of the light-emitting element may be improved. However, this aspect is an example, and the scope of the disclosure is not limited by this aspect.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display apparatus comprising:
a substrate;
a pixel electrode over the substrate;
a bank layer defining an opening exposing a central portion of the pixel electrode, and having a lateral surface facing the opening, a portion of the lateral surface of the bank layer defining a trench dug in a direction away from the opening at a lower portion of the bank layer to expose an upper surface of the pixel electrode;
an intermediate layer in the opening to correspond to the pixel electrode; and
an opposite electrode covering the bank layer and the intermediate layer.

2. The display apparatus of claim 1, wherein the pixel electrode overlapping the trench and the opening exposes a greater area of the upper surface of the pixel electrode than overlapping only the opening.

3. The display apparatus of claim 1, wherein the bank layer covers an end of the pixel electrode.

4. The display apparatus of claim 1, wherein the trench is filled with the intermediate layer.

5. The display apparatus of claim 1, wherein a width of the trench in a direction parallel to the substrate is about ¼^{th} to about ⅓^{rd} of a width of a lower surface of the bank layer in a case where the trench is not formed.

6. The display apparatus of claim 1, wherein a width of the trench in a direction parallel to the substrate is about 200 Å to about 400 Å.

7. The display apparatus of claim 1, wherein a thickness of the trench in a direction perpendicular to the substrate is about 300 Å to about 1000 Å.

8. The display apparatus of claim 1, wherein the trench comprises a lower trench depressed in lateral surfaces of the bank layer, and an upper trench that is less deeply depressed than the lower trench.

9. The display apparatus of claim 8, wherein a thickness of the trench in a direction perpendicular to the substrate is about 600 Å to about 2000 Å.

10. The display apparatus of claim 1, wherein a first pixel, a second pixel, and a third pixel respectively configured to emit light of different colors are arranged above the substrate,
wherein the pixel electrode comprises a first pixel electrode corresponding to the first pixel, a second pixel electrode corresponding to the second pixel, and a third pixel electrode corresponding to the third pixel,
wherein the bank layer defines a first opening exposing the first pixel electrode, a second opening exposing the second pixel electrode, and a third opening exposing the third pixel electrode, and
wherein the intermediate layer comprises a first intermediate layer in the first opening, a second intermediate layer in the second opening, and a third intermediate layer in the third opening.

11. The display apparatus of claim 10, wherein the first pixel is configured to emit light in a wavelength band of about 580 nm to about 780 nm,
wherein the second pixel is configured to emit light in a wavelength band of about 495 nm to about 580 nm, and
wherein the third pixel is configured to emit light in a wavelength band of about 380 nm to about 495 nm.

12. The display apparatus of claim 10, wherein the first intermediate layer and the second intermediate layer comprise an emission layer comprising quantum dots, and
wherein the third intermediate layer comprises an emission layer comprising an organic material.

13. The display apparatus of claim 12, wherein the trench is in a lateral surface of the bank layer facing the first opening and in a lateral surface of the bank layer facing the second opening, and is not in a lateral surface of the bank layer facing the third opening.

14. The display apparatus of claim 12, wherein the trench is in a lateral surface of the bank layer facing the third opening, is not in a lateral surface of the bank layer facing the first opening, and is not in a lateral surface of the bank layer facing the second opening.

15. The display apparatus of claim 12, wherein the trench is in only a lateral surface adjacent to the third opening among lateral surfaces of the bank layer facing the first opening, and is in only a lateral surface adjacent to the third opening among lateral surfaces of the bank layer facing the second opening.

16. The display apparatus of claim 12, wherein the trench is in only a lateral surface away from the third opening among lateral surfaces of the bank layer facing the first opening, is in only a lateral surface away from the third opening among lateral surfaces of the bank layer facing the second opening, and is on a lateral surface of the bank layer facing the third opening.

17. A method of manufacturing a display apparatus, the method comprising:
forming a pixel electrode over a substrate;
forming a sacrificial layer on an upper surface of the pixel electrode;
forming a bank layer on the pixel electrode;
forming an opening in the bank layer corresponding to the pixel electrode;
forming a trench in a portion of a lateral surface of the bank layer facing the opening by removing the sacrificial layer;
forming an intermediate layer in the opening to correspond to the pixel electrode; and
forming an opposite electrode covering the bank layer and the intermediate layer.

18. The method of claim 17, wherein the trench is in a lower portion of the bank layer, and exposes the upper surface of the pixel electrode.

19. The method of claim 17, wherein the sacrificial layer has a smaller area than the pixel electrode.

20. The method of claim 19, wherein the bank layer covers an end of the pixel electrode.

21. The method of claim 17, wherein the sacrificial layer comprises at least one of tungsten oxide (WOₓ) or molybdenum oxide (MoOₓ).

22. The method of claim 21, wherein the sacrificial layer is removed by washing with deionized (DI) water.

23. The method of claim 17, wherein the forming of the sacrificial layer comprises:
forming a lower sacrificial layer on the pixel electrode having an area that is less than the pixel electrode in a plan view; and
forming an upper sacrificial layer on the lower sacrificial layer having an area that less than the lower sacrificial layer in a plan view.

24. The method of claim 23, wherein the trench comprises a lower trench depressed in part of lateral surfaces of the bank layer, and an upper trench that is less deeply depressed than the lower trench.

25. The method of claim 17, wherein a first pixel, a second pixel, and a third pixel respectively configured to emit light of different colors are arranged above the substrate,
wherein the forming of the pixel electrode comprises forming a first pixel electrode corresponding to the first pixel, a second pixel electrode corresponding to the second pixel, and a third pixel electrode corresponding to the third pixel,
wherein the forming of the bank layer comprises forming a first opening exposing the first pixel electrode, a second opening exposing the second pixel electrode, and a third opening exposing the third pixel electrode, and
wherein the forming of the intermediate layer comprises forming a first intermediate layer in the first opening, a second intermediate layer in the second opening, and a third intermediate layer in the third opening.

26. The method of claim 25, wherein the forming of the intermediate layer comprises:
discharging a material for forming an emission layer into the opening through an inkjet process; and
drying the material for forming the emission layer.

27. The method of claim 26, wherein each of the forming of the first intermediate layer and the forming of the second intermediate layer comprises forming an emission layer comprising quantum dots, and
wherein the forming of the third intermediate layer comprises forming an emission layer comprising an organic material.

28. The method of claim 27, wherein the trench is in only a lateral surface of the bank layer facing the first opening and a lateral surface of the bank layer facing the second opening.

29. The method of claim 28, wherein the drying is adjusted to a drying condition of the third intermediate layer.

30. The method of claim 27, wherein the trench is in only a lateral surface of the bank layer facing the third opening.

31. The method of claim 30, wherein the drying is adjusted to drying conditions of the first intermediate layer and the second intermediate layer.

32. The method of claim 27, wherein the trench is in only a lateral surface adjacent to the third opening among lateral surfaces of the bank layer facing the first opening, and is in only a lateral surface adjacent to the third opening among lateral surfaces of the bank layer facing the second opening.

33. The method of claim 27, wherein the trench is in only a lateral surface away from the third opening among lateral surfaces of the bank layer facing the first opening, is in only a lateral surface away from the third opening among lateral surfaces of the bank layer facing the second opening, and is in a lateral surface of the bank layer facing the third opening.
